(19) United States
(12) Patent Application Publication
(10) Pub. No.: US 2024/0397726 A1
(43) Pub. Date: Nov. 28, 2024

(54) SEMICONDUCTOR DEVICE AND ELECTRONIC SYSTEM HAVING THE SAME

(71) Applicant: Samsung Electronics Co., Ltd., Suwon-si (KR)

(72) Inventors: Ilho Myeong, Suwon-si (KR); Yongseok Kim, Suwon-si (KR); Taeyoung Kim, Suwon-si (KR); Suseong Noh, Suwon-si (KR); Sanghyun Park, Suwon-si (KR); Suhwan Lim, Suwon-si (KR); Daewon Ha, Suwon-si (KR)

(21) Appl. No.: 18/655,488

(22) Filed: May 6, 2024

(30) Foreign Application Priority Data
May 25, 2023 (KR) 10-2023-0067728

(51) Int. Cl. H10B 51/20; H01L 25/065; H01L 29/66; H01L 29/78; H10B 51/10; H10B 80/00

(52) U.S. Cl. CPC H10B 51/20; H01L 25/0652; H01L 29/6684; H01L 29/78391; H10B 51/10; H10B 80/00; H01L 2225/06506

(57) ABSTRACT

A semiconductor device includes a stacked structure including a plurality of gate lines and a plurality of insulation patterns that are alternately stacked in a vertical direction, where the stacked structure defines a vertical hole that extends into the stacked structure and in the vertical direction, a channel film that extends into a vertical hole, and a multiple dielectric layer structure between the channel film and the stacked structure, where the multiple dielectric layer structure includes a plurality of interlayer dielectric layers and a plurality of ferroelectric layers that are alternately stacked and extend from the channel film toward the stacked structure, and where an inner ferroelectric layer of the plurality of ferroelectric layers is thicker than an outer ferroelectric layer of the plurality of ferroelectric layers.

### CROSS-REFERENCE TO RELATED APPLICATIONS

This application is based on and claims priority under 35 U.S.C. § 119 to Korean Patent Application No. 10-2023-0067728, filed on May 25, 2023, in the Korean Intellectual Property Office, the disclosure of which is incorporated by reference herein in its entirety.

### TECHNICAL FIELD

The present disclosure relates to a semiconductor device and an electronic system including the same, and more particularly, to a semiconductor device including a vertical memory device including a ferroelectric field effect transistor (FeFET) and an electronic system including the same.

### BACKGROUND

Ferroelectrics are materials having ferroelectricity that maintain spontaneous polarization by aligning electric dipole moments even when no external electric field is applied to the ferroelectrics. Ferroelectrics have a characteristic in which polarization (or an electric field) remains semi-permanently therein even when a voltage returns to 0V after application of a certain voltage to the ferroelectrics.

With the increases in capacity and integration of semiconductor devices, a vertical memory device that increases memory capacity by stacking a plurality of memory cells vertically on a substrate has been proposed, and research for applying ferroelectrics to such a vertical memory device is being done.

### SUMMARY

The present disclosure provides a semiconductor device having a structure capable of improving electrical characteristics and reliability in a semiconductor device having memory cells three-dimensionally arranged in a region downsized through down-scaling.

The present disclosure also provides an electronic system including a semiconductor device having a structure capable of improving electrical characteristics and reliability in a semiconductor device having memory cells three-dimensionally arranged in a region downsized through down-scaling.

According to an aspect of the present disclosure, a semiconductor device includes a stacked structure including a plurality of gate lines and a plurality of insulation patterns that are alternately stacked in a vertical direction, where the stacked structure defines a vertical hole that extends into the stacked structure and in the vertical direction; a channel film that extends into the vertical hole; and a multiple dielectric layer structure between the channel film and the stacked structure, where the multiple dielectric layer structure includes a plurality of interlayer dielectric layers and a plurality of ferroelectric layers that are alternately stacked and extend from the channel film toward the stacked structure, where an inner ferroelectric layer of the plurality of ferroelectric layers is thicker than an outer ferroelectric layer of the plurality of ferroelectric layers.

According to another aspect of the present disclosure, a semiconductor device includes a conductive layer; a stacked structure on the conductive layer, where the stacked structure includes a plurality of gate lines that are spaced apart from each other in a vertical direction and overlap each other in the vertical direction, where the stacked structure includes a plurality of insulation patterns that are respectively between the plurality of gate lines, and where the stacked structure defines a vertical hole that extends into the stacked structure and in the vertical direction; a conductive pad on the stacked structure and spaced apart from the conductive layer in the vertical direction; a channel film in the vertical hole, where a first end of the channel film contacts the conductive layer and a second end of the channel film contacts the conductive pad; and a multiple dielectric layer structure that extends in the vertical direction and is on an outer wall of the channel film in the vertical hole, where the multiple dielectric layer structure includes a plurality of interlayer dielectric layers and a plurality of ferroelectric layers that are alternately stacked on the outer wall of the channel film, and an inner ferroelectric layer of the plurality of ferroelectric layers is thicker than an outer ferroelectric layer of the plurality of ferroelectric layers.

According to another aspect of the present disclosure, an electronic system includes a main substrate; a semiconductor device on the main substrate; and a controller electrically connected to the semiconductor device on the main substrate, where the semiconductor device includes: a stacked structure including a plurality of gate lines and a plurality of insulation patterns that are alternately stacked in a vertical direction, where the stacked structure defines a vertical hole that extends into the stacked structure and in the vertical direction; a channel film extending in the vertical direction and in the vertical hole; and a multiple dielectric layer structure between the channel film and the stacked structure, where the multiple dielectric layer structure includes a plurality of interlayer dielectric layers and a plurality of ferroelectric layers that are alternately stacked and extend from the channel film toward the stacked structure, and where an inner ferroelectric layer of the plurality of ferroelectric layers is thicker than an outer ferroelectric layer of the plurality of ferroelectric layers.

### BRIEF DESCRIPTION OF THE DRAWINGS

Embodiments of the present disclosure will be more clearly understood from the following detailed description taken in conjunction with the accompanying drawings in which:

FIG. 1 is a block diagram showing a semiconductor device according to embodiments of the present disclosure;

FIG. 2A is a plan layout showing some components of a cell array structure of a semiconductor device according to embodiments of the present disclosure;

FIG. 2B is a cross-sectional view of some regions along a line X1-X1′ of FIG. 2A;

FIG. 2C is an enlarged cross-sectional view of a region indicated by “EX1” in FIG. 2B;

FIG. 2D is an enlarged cross-sectional view of a region indicated by “EX2” in FIG. 2C;

FIG. 2E is a plan view of the configuration of the semiconductor device shown in FIG. 2C at a first vertical level;

FIG. 3 shows polarization-voltage (P-V) hysteresis curves of a semiconductor device according to a comparative example and a semiconductor device according to embodiments of the present disclosure;

FIG. 4 is a cross-sectional view of a semiconductor device according to other embodiments of the present disclosure;

FIG. 5 is a cross-sectional view of a semiconductor device according to other embodiments of the present disclosure;

FIGS. 6A and 6B are diagrams of a semiconductor device according to other embodiments of the present disclosure;

FIGS. 7A, 7B, and 7C are diagrams pf a semiconductor device according to other embodiments of the present disclosure;

FIGS. 8A, 8B, 8C, and 8D are diagrams of a semiconductor device according to other embodiments of the present disclosure;

FIGS. 9A, 9B, 9C, 9D, and 9E are cross-sectional views describing a method of manufacturing a semiconductor device according to embodiments of the present disclosure and are enlarged views of a region corresponding to the region indicated by “EX1” in FIG. 2B according to a process sequence;

FIG. 10 is a diagram schematically showing an electronic system including a semiconductor device according to an embodiment of the present disclosure;

FIG. 11 is a schematic perspective view of an electronic system including a semiconductor device according to an embodiment of the present disclosure; and

FIG. 12 is a schematic cross-sectional view of semiconductor packages according to embodiments.

### DETAILED DESCRIPTION OF THE EMBODIMENTS

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection. The phrase “an element A surrounds element B” may refer to element A at least partially surrounding element B. The phrases “an element A is filled with element B” or “element B fills element A” refer to element B being at least partially in a space defined by element A. As used herein, “an element A is at a same level as element B” refers to at least one surface of element A that is coplanar with at least one surface of element B.

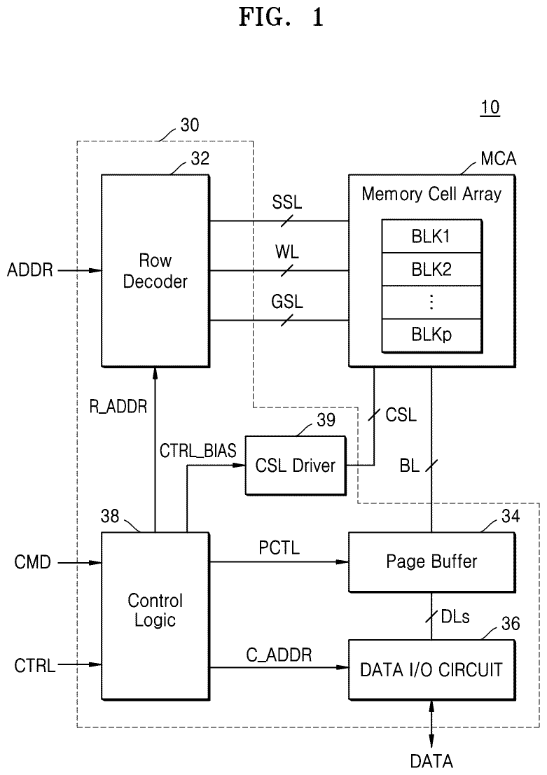

FIG. 1 is a block diagram showing a semiconductor device 10 according to embodiments.

Referring to FIG. 1, the semiconductor device 10 may include a memory cell array MCA and a peripheral circuit 30. The memory cell array MCA includes a plurality of memory cell blocks BLK1, BLK2, . . . , and BLKp. The plurality of memory cell blocks BLK1, BLK2, . . . , and BLKp may each include a plurality of memory cells. The plurality of memory cell blocks BLK1, BLK2, . . . , and BLKp may be connected to the peripheral circuit 30 through a bit line BL, a word line WL, a string select line SSL, and a ground select line GSL.

The peripheral circuit 30 may include a row decoder 32, a page buffer 34, a data input/output circuit 36, a control logic 38, and a common source line driver 39. The peripheral circuit 30 may further include various circuits, such as a voltage generating circuit for generating various voltages for operating the semiconductor device 10, an error correction circuit for correcting errors in data read from the memory cell array MCA, and an input/output interface.

The memory cell array MCA may be connected to the row decoder 32 through the word line WL, the string select line SSL, and the ground select line GSL and may be connected to the page buffer 34 through the bit line BL. In the memory cell array MCA, the memory cells included in each of the plurality of memory cell blocks BLK1, BLK2, . . . , and BLKp may each be a flash memory cell. The memory cell array MCA may include a three-dimensional (3D) memory cell array. The 3D memory cell array may include a plurality of NAND strings, and the plurality of NAND strings may each include a plurality of memory cells connected to a plurality of word lines WL that are vertically stacked.

The peripheral circuit 30 may receive an address ADDR, a command CMD, and a control signal CTRL from a device outside the semiconductor device 10 and may transmit and receive data DATA to and from the device outside the semiconductor device 10.

The row decoder 32 may select at least one of the plurality of memory cell blocks BLK1, BLK2, . . . , and BLKp in response to an address ADDR from the outside and select the word line WL, the string select line SSL, and the ground select line GSL corresponding to a selected memory cell block. The row decoder 32 may transmit a voltage for performing a memory operation to the word line WL corresponding to the selected memory cell block.

The page buffer 34 may be connected to the memory cell array MCA through the bit line BL. The page buffer 34 may operate as a write driver during a program operation and apply a voltage according to the data DATA to be stored in the memory cell array MCA to the bit line BL and may operate as a sense amplifier during a read operation and sense the data DATA stored in the memory cell array MCA. The page buffer 34 may operate according to a control signal PCTL provided from the control logic 38.

The data input/output circuit 36 may be connected to the page buffer 34 through a plurality of data lines DLs. During a program operation, the data input/output circuit 36 may receive the data DATA from a memory controller (not shown) and provide the data DATA to be programmed to the page buffer 34 based on a column address C_ADDR provided from the control logic 38. The data input/output circuit 36 may provide the data DATA to be read stored in the page buffer 34 to the memory controller based on the column address C_ADDR provided from the control logic 38 during a read operation.

The data input/output circuit 36 may transmit an address or a command input thereto to the control logic 38 or the row decoder 32. The peripheral circuit 30 may further include an electrostatic discharge (ESD) circuit and a pull-up/pull-down driver.

The control logic 38 may receive a command CMD and a control signal CTRL from the memory controller. The control logic 38 may provide a row address R_ADDR to the row decoder 32 and provide the column address C_ADDR to the data input/output circuit 36. The control logic 38 may generate various internal control signals used in the semiconductor device 10 in response to the control signal CTRL. For example, the control logic 38 may adjust the level of a voltage provided to the word line WL and the bit line BL when a memory operation like a program operation or an erase operation is performed.

The common source line driver 39 may be connected to the memory cell array MCA through a common source line CSL. The common source line driver 39 may apply a common source voltage (e.g., power voltage) or a ground voltage to the common source line CSL based on a control signal CTRL_BIAS of the control logic 38.

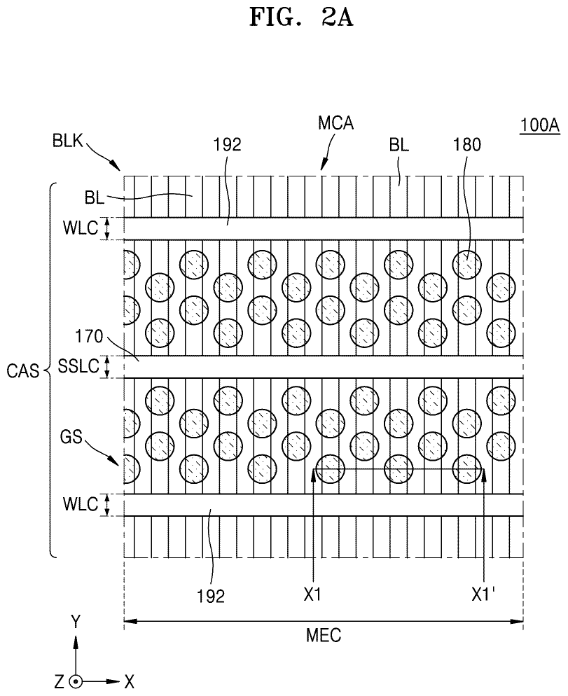

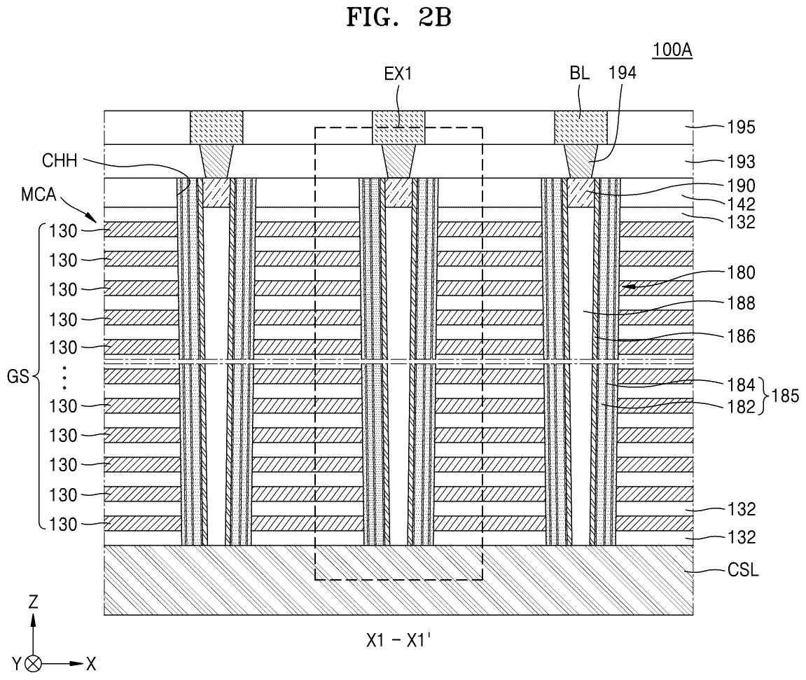

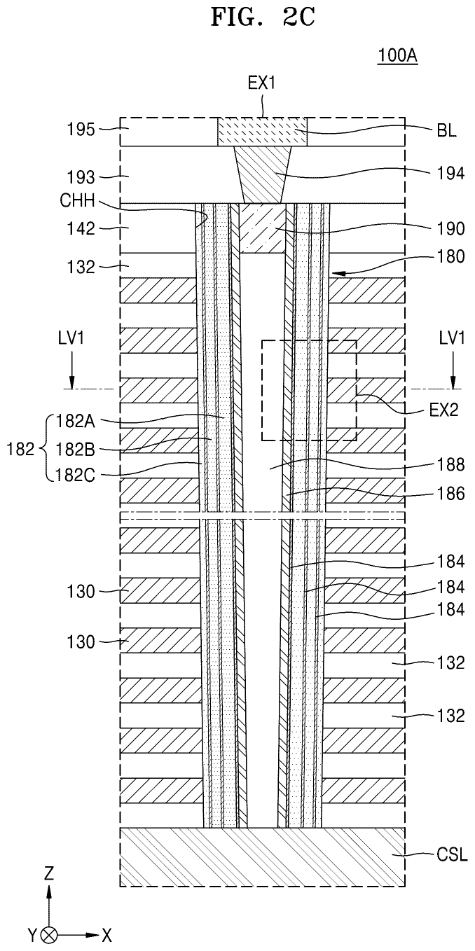

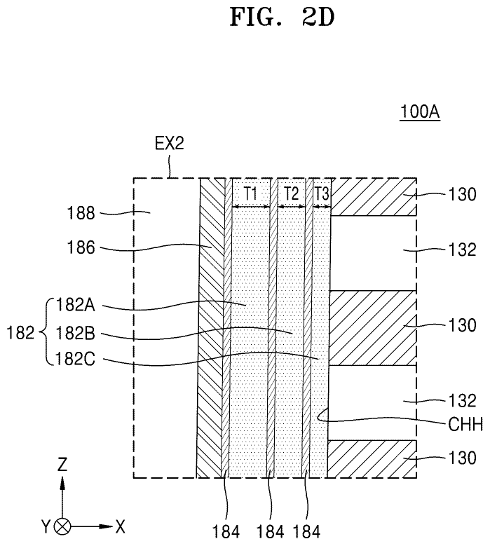

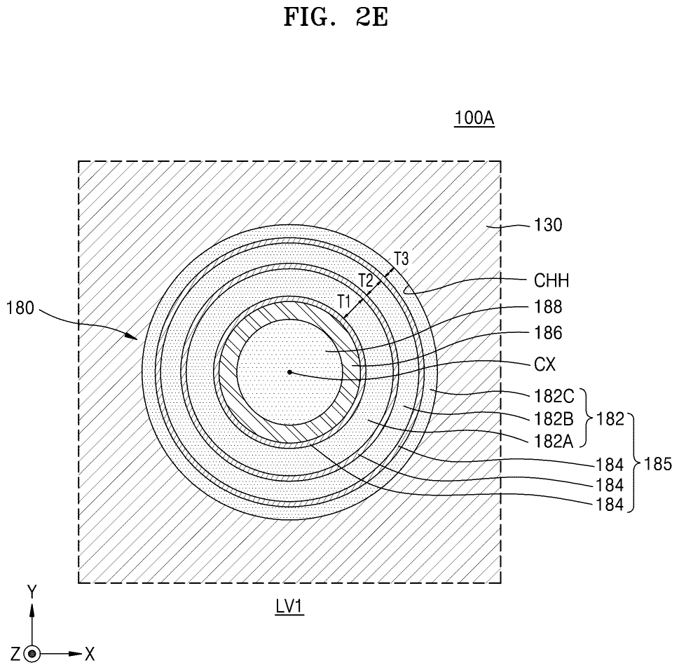

FIG. 2A is a plan layout showing some components of a cell array structure CAS of a semiconductor device 100A according to embodiments. FIG. 2B is a cross-sectional view of some regions along a line X1-X1′ of FIG. 2A. FIG. 2C is an enlarged cross-sectional view of a region indicated by “EX1” in FIG. 2B. FIG. 2D is an enlarged cross-sectional view of a region indicated by “EX2” in FIG. 2C. FIG. 2E is a plan view of the configuration of the semiconductor device shown in FIG. 2C at a first vertical level LV1. FIGS. 2A and 2B show some configurations of a memory cell block BLK corresponding to one selected from among the plurality of memory cell blocks BLK1, BLK2, . . . , and BLKp shown in FIG. 1.

Referring to FIGS. 2A to 2E, the semiconductor device 100A may include the cell array structure CAS, and the cell array structure CAS may include a memory cell region MEC in which the memory cell array MCA is disposed.

The cell array structure CAS may include the common source line CSL and the memory cell array MCA disposed on the common source line CSL. The memory cell array MCA may include a gate stack GS including a plurality of gate lines 130. The plurality of gate lines 130 included in the gate stack GS may extend in a horizontal direction parallel to the common source line CSL and may overlap one another in a vertical direction (Z direction). The plurality of gate lines 130 may include the plurality of word lines WL, the ground select line GSL, and the string select line SSL shown in FIG. 1.

As shown in FIG. 2B, the cell array structure CAS may include a stacked structure including a gate stack GS and a plurality of insulation patterns 132. The gate stack GS may include a plurality of gate lines 130 overlapping each other in the vertical direction (Z direction) on the common source line CSL and spaced apart from each other in the vertical direction (Z direction). The plurality of insulation patterns 132 may each be interposed between the common source line CSL and the plurality of gate lines 130 and between the plurality of gate lines 130. The stacked structure may further include an intermediate insulation layer 142 covering or overlapping the uppermost insulation pattern 132 from among the plurality of insulation patterns 132. From among the plurality of gate lines 130, a gate line 130 closest to a conductive pad 190 may be covered or overlapped by the insulation pattern 132 and the intermediate insulation layer 142. The plurality of insulation patterns 132 and the intermediate insulation layer 142 may include silicon oxide, silicon nitride, or SiON.

A plurality of conductive pads 190 may be arranged at positions spaced apart from the common source line CSL in the vertical direction (Z direction) with a multi-layer structure including the plurality of gate lines 130 and the plurality of insulation patterns 132 therebetween. The common source line CSL may be referred to as a conductive layer herein.

The plurality of gate lines 130 may each include a metal, a conductive metal nitride, a metal silicide, a semiconductor doped with impurities, or a combination thereof. For example, the plurality of gate lines 130 may each include tungsten, nickel, cobalt, tantalum, tungsten nitride, titanium nitride, tantalum nitride, doped polysilicon, tungsten silicide, nickel silicide, cobalt silicide, tantalum silicide, or a combination thereof, but the present disclosure is not limited thereto.

The plurality of conductive pads 190 and the common source line CSL may each include a semiconductor material, a metal, a conductive metal nitride, or a combination thereof. For example, the plurality of conductive pads 190 and the common source line CSL may each include doped polysilicon, tungsten, titanium, tantalum, copper, aluminum, titanium nitride, tantalum nitride, tungsten nitride, or a combination thereof, but the present disclosure is not limited thereto.

The cell array structure CAS may include a plurality of vertical holes CHH extending through the stacked structure in the vertical direction (Z direction) and a plurality of channel structures 180 respectively arranged in the plurality of vertical holes CHH. The plurality of channel structures 180 may each include a multiple dielectric layer 185, a channel film 186, and an insulation plug 188 that are sequentially stacked in a direction from the plurality of gate lines 130 toward a center CX of the channel structure 180. The multiple dielectric layer 185 may also be referred to herein as “the multiple dielectric layer structure 185.”

A channel film 186 may extend long in the vertical direction (Z direction) within a vertical hole CHH. An end of the channel film 186 in the vertical direction (Z direction) may contact the conductive pad 190 and the other end of the channel film 186 in the vertical direction (Z direction) may contact the common source line CSL. The insulation plug 188 may be surrounded by the channel film 186. According to some embodiments, the channel film 186 may have a hollow cylindrical shape, and the insulation plug 188 may extend in the vertical direction (Z direction) in a space defined by the inner wall of the channel film 186.

According to some embodiments, the channel film 186 may include polysilicon, an oxide semiconductor, a two-dimensional semiconductor material, or a combination thereof. The polysilicon may include doped polysilicon but is not limited thereto.

An oxide semiconductor that may be used to form the channel film 186 may be selected from among IGZO (InGaZnO), Sn-IGZO, IWO (InWO), IZO (InZnO), ZTO (ZnSnO), ZnO, YZO (yttrium-doped zinc oxide), IGSO (InGaSiO), InO, SnO, TiO, ZnON, MgZnO, ZrInZnO, Hf InZnO, SnInZnO, SiInZnO, GaZnSnO, ZrZnSnO, or combinations thereof. According to embodiments, at least a portion of the channel film 186 may include the same elements as the elements constituting an oxide semiconductor layer constituting the channel film 186 and may further include at least one dopant selected from among aluminum (Al), boron (B), arsenic (As), fluorine (F), and hydrogen (H).

According to embodiments, the two-dimensional semiconductor material that may be used to form the channel film 186 may be selected from among graphene, black phosphorous, a transition metal chalcogen compound, or a combination thereof. The transition metal chalcogen compound may include a combination of a transition metal selected from among Ni, Cu, Zn, Mo, W, Nb, V, Ta, Ti, Zr, Hf, Tc, and Re and a chalcogen group element selected from among S, Se, and Te. For example, the channel film 186 may include MoS₂, MoSe₂, MoTe₂, WS₂, WSc₂, WTC₂, ZrS₂, ZrSc₂, HfS₂, HfSc₂, NbSc₂, ReSc₂, CuS, or a combination thereof but is not limited thereto.

According to other embodiments, the two-dimensional semiconductor material that may be used to form the channel film 186 may include a chalcogenide material including a non-transition metal. The non-transition metal may be selected from among Ga, In, Sn, Ge, and Pb. For example, the channel film 186 may include SnSe₂, GaS, GaSe, GaTe, GeSe, In₂Sc₃, InSnS₂, or a combination thereof but is not limited thereto.

According to other embodiments, the channel film 186 may include a p-type oxide semiconductor, an n-type oxide semiconductor, or a combination thereof. The p-type oxide semiconductor may be selected from among nickel oxide (NiO), copper oxide, tin oxide (SnO), copper aluminum oxide (CuAlO₂), copper chromium oxide (CuCrO₂), beta tellurium dioxide (β-TeO2), or a combination thereof. The copper oxide may include CuO or Cu₂O but is not limited thereto. The n-type oxide semiconductor may be selected from among indium oxide (In₂O₃), tin oxide (SnO₂), zinc oxide (ZnO), IGZO, or a combination thereof. The tin oxide may exhibit p-type characteristics when present in the form of SnO and exhibit n-type characteristics when present in the form of SnO₂.

According to embodiments, the channel film 186 may further include a p-type dopant or an n-type dopant to adjust carrier mobility in the channel film 186. The channel film 186 may have a thickness from about 1 nm to about 20 nm in a horizontal direction (e.g., from about 5 nm to about 18 nm) but is not limited thereto.

The multiple dielectric layer 185 may be disposed between the channel film 186 and the plurality of gate lines 130. The multiple dielectric layer 185 may include a plurality of interlayer dielectric layers 184 and a plurality of ferroelectric layers 182 alternately stacked on the outer wall of the channel film 186. For example, the multiple dielectric layer 185 may horizontally surround the outer wall of the channel film 186.

According to some embodiments, the plurality of ferroelectric layers 182 may include a first ferroelectric layer 182A, a second ferroelectric layer 182B, and a third ferroelectric layer 182C that are sequentially arranged in a direction from the channel film 186 toward the plurality of gate lines 130 and spaced apart from one another in a horizontal direction (X direction and/or Y direction). For example, when viewed from above, the first ferroelectric layer 182A may surround the channel film 186, the second ferroelectric layer 182B may surround the first ferroelectric layer 182A, and the third ferroelectric layer 182C may surround the second ferroelectric layer 182B. The plurality of interlayer dielectric layers 184 may each be disposed between the channel film 186 and the plurality of ferroelectric layers 182 and between the plurality of ferroelectric layers 182. For example, the plurality of interlayer dielectric layers 184 may each be disposed between the channel film 186 and the first ferroelectric layer 182A, between the first ferroelectric layer 182A and the second ferroelectric layer 182B, and between the second ferroelectric layer 182B and the third ferroelectric layer 182C. From among the plurality of interlayer dielectric layers 184, the innermost interlayer dielectric layer 184 may contact the outer wall of the channel film 186, and the outer wall of the third ferroelectric layer 182C may contact the plurality of gate lines 130. According to embodiments, the channel film 186, the plurality of interlayer dielectric layers 184, and the plurality of ferroelectric layers 182 may have horizontal cross-sections having concentric circular shapes.

According to some embodiments, the multiple dielectric layer 185 may extend in the vertical direction (Z direction) while surrounding the outer wall of the channel film 186 in the vertical hole CHH. For example, the channel film 186, the plurality of interlayer dielectric layers 184, and the plurality of ferroelectric layers 182 may have coaxial cylindrical shapes. For example, the third ferroelectric layer 182C may contact the plurality of gate lines 130 and the insulation pattern 132 in the vertical hole CHH and extend long in the vertical direction (Z direction).

While FIGS. 2B to 2E show that the plurality of interlayer dielectric layers 184 and the plurality of ferroelectric layers 182 include three layers each, the present disclosure is not limited thereto. For example, the plurality of ferroelectric layers 182 may include two layers or four or more layers spaced apart from one another, and the plurality of interlayer dielectric layers 184 may be arranged between the channel film 186 and the plurality of ferroelectric layers 182 and between the plurality of ferroelectric layers 182.

According to embodiments, an inner ferroelectric layer 182 from among the plurality of ferroelectric layers 182 may have a greater thickness than an outer ferroelectric layer 182 from among the plurality of ferroelectric layers 182. For example, the thickness of the plurality of ferroelectric layers 182 may increase toward the channel film 186. In this specification, the thickness of an arbitrary ferroelectric layer 182 refers to the difference between the distance from the center CX of the channel structure 180 to the outer wall of the arbitrary ferroelectric layer 182 and the distance from the center CX of the channel structure 180 to the inner wall of the arbitrary ferroelectric layer 182, and the same may also be applied to the thickness of the channel film 186 and the thickness of the arbitrary interlayer dielectric layer 184.

A first thickness T1, which is the thickness of the first ferroelectric layer 182A, may be greater than a second thickness T2, which is the thickness of the second ferroelectric layer 182B, and the second thickness T2 of the second ferroelectric layer 182B may be greater than a third thickness T3, which is the thickness of the third ferroelectric layer 182C.

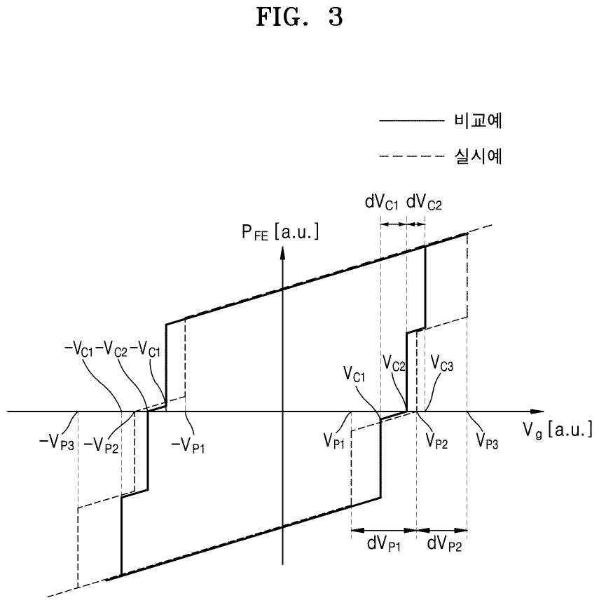

FIG. 3 shows polarization-voltage (P-V) hysteresis curves of a semiconductor device according to a comparative example and the semiconductor device 100A according to embodiments. In detail, the semiconductor device according to comparative example includes three ferroelectric layers 182 and has the same structure as the semiconductor device 100A according to embodiments, except that all of the first ferroelectric layers 182A, the second ferroelectric layers 182B, and the third ferroelectric layers 182C have the same thickness.

Referring to FIG. 3, both the semiconductor device according to the comparative example and the semiconductor device 100A according to the example embodiments include three ferroelectric layers 182 surrounding a cylindrical channel film 186, thus having a multiple level polarization state. In this specification, “multiple level” indicates that there are a plurality of polarization states having convergence values within a certain voltage range. As the voltage applied to the channel film 186 increases, the polarization state of each of the plurality of ferroelectric layers 182 abruptly changes at first to third switching voltages in the order close to the channel film 186 where an electric field is concentrated. For example, the polarization state of the first ferroelectric layer 182A is changed at a first switching voltage, the polarization state of the second ferroelectric layer 182B is changed at a second switching voltage, and the polarization state of the third ferroelectric layer 182C is changed at a third switching voltage. As described above, a multi-level cell storing a plurality of bits in one memory cell may be implemented based on multiple dielectric films having multiple level polarization states. In this specification, a switching voltage refers to a voltage at a point where the polarization state of a plurality of ferroelectric layers rapidly changes as a voltage applied to a channel film increases. The switching voltage may correspond to a coercive field (Ec), which is a point at which the direction of polarization of each ferroelectric layer is changed when the x-axis in the coordinate system of FIG. 3 is converted into an electric field.

Referring to FIG. 3, according to the comparative example, the absolute value of the difference between a first switching voltage V_{C1} and a second switching voltage V_{C2} is a first voltage difference dV_{C1}, and the absolute value of the difference between the second switching voltage V_{C2} and a third switching voltage V_{C3} is a second voltage difference dV_{C2}. In the semiconductor device 100A according to example embodiments, the absolute value of the difference between a first switching voltage V_{P1} and a second switching voltage V_{P2} is a first voltage difference dV_{P1}, and the absolute value of the difference between the second switching voltage V_{P2} and a third switching voltage V_{P3} is a second voltage difference dV_{P2}. Referring to FIG. 3, it may be seen that the first voltage difference dV_{P1} of the semiconductor device 100A is greater than the first voltage difference dV_{C1} according to the comparative example, and the second voltage difference dV_{P2} of the semiconductor device 100A is greater than the second voltage difference dV_{C2} according to the comparative example.

Since the semiconductor device 100A according to embodiments includes the plurality of ferroelectric layers 182 having a thickness increasing toward the channel film 186, a voltage interval between switching voltages adjacent to each other may increase. Therefore, a voltage variation margin for implementing multi-bits may be secured, and thus, the operational reliability of the semiconductor device 100A may be improved.

According to embodiments, the plurality of ferroelectric layers 182 may include a monocrystalline ferroelectric material. The plurality of ferroelectric layers 182 including a monocrystalline ferroelectric material have a characteristic that an Ec value changes according to the thickness thereof. For example, the thicker the ferroelectric layer 182, the lower the Ec value may be. For example, as the thickness of the first ferroelectric layer 182A on which an electric field is concentrated is increased to lower the first switching voltage V_{C1} and the thickness of the third ferroelectric layer 182C is reduced to increase the third switching voltage V_{C3}, the interval between the first to third switching voltages V_{C1}, V_{C2}, and V_{C3} may be widened.

According to some embodiments, a plurality of ferroelectric layers 182 may not include a polycrystalline ferroelectric material. A polycrystalline ferroelectric layer may not exhibit the characteristic that the Ec value tends to change according to the thickness thereof. For example, grains of a polycrystalline ferroelectric layer may have Ec values different from one another, and thus, the polycrystalline ferroelectric layer may have a constant or irregular Ec distribution regardless of the thickness thereof. The PV hysteresis curves shown as the comparative example in FIG. 3 may represent the PV hysteresis curve of a plurality of polycrystalline ferroelectric layers having a thickness increasing in the inward direction.

According to some embodiments, the plurality of ferroelectric layers 182 may include the same material. In the semiconductor device 100A according to embodiments, the plurality of ferroelectric layers 182 may include the same material and have different thicknesses instead of forming the plurality of ferroelectric layers 182 using different materials to realize different Ec values, thereby implementing stable multi-bits and improving the manufacturing efficiency of the semiconductor device 100A.

According to some embodiments, the difference between thicknesses of the plurality of ferroelectric layers 182 may be constant. For example, the difference between the first thickness T1 of the first ferroelectric layer 182A and the second thickness T2 of the second ferroelectric layer 182B may be equal to the difference between the second thickness T2 of the second ferroelectric layer 182B and the third thickness T3 of the third ferroelectric layer 182C.

According to some other embodiments, the difference between thicknesses of the plurality of ferroelectric layers 182 may not be constant. According to an embodiment, the difference between the first thickness T1 of the first ferroelectric layer 182A and the second thickness T2 of the second ferroelectric layer 182B may be smaller than the difference between the second thickness T2 of the second ferroelectric layer 182B and the third thickness T3 of the third ferroelectric layer 182C. According to another embodiment, the difference between the first thickness T1 of the first ferroelectric layer 182A and the second thickness T2 of the second ferroelectric layer 182B may be greater than the difference between the second thickness T2 of the second ferroelectric layer 182B and the third thickness T3 of the third ferroelectric layer 182C. According to some other embodiments, the plurality of ferroelectric layers 182 may include four or more ferroelectric layers 182, the difference between thicknesses of two ferroelectric layers 182 adjacent to each other of some ferroelectric layers 182 may be the same, and the difference between thicknesses of the other two ferroelectric layers 182 adjacent to each 182 may not be the same.

According to some embodiments, the plurality of ferroelectric layers 182 may each have a thickness from about 0.1 nm to about 20 nm, and the thicknesses may be independent of each other. When the thickness of each of the plurality of ferroelectric layers 182 is less than 0.1 nm, the Ec value may be excessively reduced, and thus, a margin for voltage variation to implement multi-bits may not be secured. When the thickness of each of the plurality of ferroelectric layers 182 exceeds 20 nm, the polarization characteristics may disappear, and thus, the function as a memory device may not be implemented.

According to some embodiments, the plurality of ferroelectric layers 182 may include at least one oxide of a material selected from among Hf, Si, Al, Zr, Y, La, Gd, and Sr. For example, the plurality of ferroelectric layers 182 may comprise at least one of hafnium oxide (HfO), hafnium zirconium oxide (HfZrO), hafnium titanium oxide (HfTiO), or hafnium silicon oxide (Si: HfO). The ferroelectric material may further include a dopant as needed. The dopant may include at least one element selected from among Si, Al, Zr, Y, La, Gd, Sc, Sr, Mg, and Ba but is not limited thereto. The terms like “HfO”, “ZrO”, and “HfZrO” used herein refer to materials composed of elements included in the respective terms and are not chemical formulas indicating stoichiometric relationships.

According to some embodiments, the plurality of interlayer dielectric layers 184 may each have a thickness in a range from about 0.01 nm to about 5 nm, and the thicknesses may be independent of each other.

According to some embodiments, the plurality of interlayer dielectric layers 184 may include at least one selected from a silicon oxide layer and a high-k layer having a higher dielectric constant than the silicon oxide layer. The high-k layer may include hafnium oxide (HfO), aluminum oxide (AlO), hafnium aluminum oxide (HfAlO), tantalum oxide (TaO), titanium oxide (TiO), or a combination thereof. Therefore, memory cells may be driven with a relatively low voltage, and electrical characteristics of the semiconductor device 100A may be improved.

The insulation plug 188 may be disposed in a columnar space defined by the channel film 186. The insulation plug 188 may fill a space between the conductive pad 190 and the common source line CSL in the columnar space defined by the channel film 186. The insulation plug 188 may have a surface in contact with the channel film 186. The insulation plug 188 may include a silicon oxide film but is not limited thereto.

A plurality of bit lines BL may be arranged on the plurality of channel structures 180 in the cell array structure CAS. A plurality of bit line contact pads 194 may be arranged between the plurality of channel structures 180 and the plurality of bit lines BL, respectively. The conductive pad 190 disposed on one end of each of the plurality of channel structures 180 may be connected to a corresponding one of the plurality of bit lines BL through a bit line contact pad 194. The plurality of bit line contact pads 194 may be insulated from each other by a first upper insulation layer 193, and the plurality of bit lines BL may be insulated from each other by a second upper insulation layer 195.

According to some embodiments, the plurality of bit line contact pads 194 and the plurality of bit lines BL may each include a metal, a conductive metal nitride, or a combination thereof. For example, the plurality of bit line contact pads 194 and the plurality of bit lines BL may each include tungsten, titanium, tantalum, copper, aluminum, titanium nitride, tantalum nitride, tungsten nitride, or a combination thereof. The first upper insulation layer 193 and the second upper insulation layer 195 may each include a silicon oxide layer, a silicon nitride layer, or a combination thereof.

As shown in FIG. 2A, a plurality of word line cut regions WLC may extend in a first horizontal direction (X direction) in the cell array structure CAS. The plurality of word line cut regions WLC may limit the width of the gate stack GS in a second horizontal direction (Y direction). The plurality of word line cut regions WLC may be filled with a word line cut structure 192. According to some embodiments, the word line cut structure 192 may include an insulation layer, a polysilicon layer, a metal layer, or a combination thereof. According to some embodiments, the word line cut structure 192 may include a silicon oxide layer, a silicon nitride layer, a polysilicon layer, a tungsten layer, or a combination thereof but is not limited thereto.

In the memory cell array MCA, two string select lines SSL (refer to FIG. 1) adjacent to each other in the second horizontal direction (Y direction) may be spaced apart from each other with a string select line cut region SSLC therebetween. The string select line cut region SSLC may be filled with an insulation layer 170. According to some embodiments, the insulation layer 170 may include an oxide layer, a nitride layer, or a combination thereof. According to some embodiments, at least a portion of the string select line cut region SSLC may be filled with an air gap. The term “air” used herein may refer to the atmosphere or other gases that may be present during a manufacturing process.

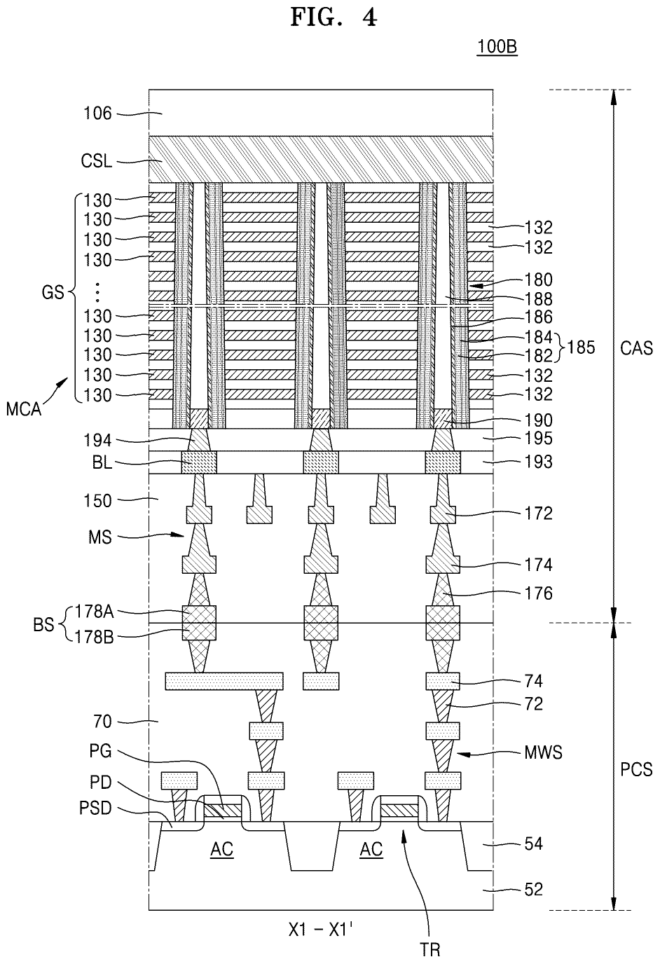

FIG. 4 is a cross-sectional view for describing a semiconductor device 100B according to other embodiments. In FIG. 4, the same reference numerals as those in FIGS. 2A to 2D denote the same members, and detailed descriptions thereof will be omitted below.

Referring to FIG. 4, the semiconductor device 100B may include the cell array structure CAS and a peripheral circuit structure PCS that overlap each other in the vertical direction (Z direction). The cell array structure CAS may include the memory cell region MEC in which the memory cell array MCA is disposed.

According to embodiments, the semiconductor device 100B may have a chip-to-chip (C2C) structure. The C2C structure may be obtained by forming the cell array structure CAS on a first wafer, forming the peripheral circuit structure PCS on a second wafer that is different from the first wafer, and then connecting the cell array structure CAS and the peripheral circuit structure PCS to each other by using a bonding method. For example, the bonding method may refer to a method of bonding a first bonding metal pad 178A formed on the uppermost metal layer of the cell array structure CAS and a second bonding metal pad 178B formed on the uppermost metal layer of the peripheral circuit structure PCS to be electrically connectable to each other. According to embodiments, when the first bonding metal pad 178A and the second bonding metal pad 178B include copper (Cu), the bonding method may be a Cu—Cu bonding method. According to other embodiments, the first bonding metal pad 178A and the second bonding metal pad 178B may each include aluminum (Al) or tungsten (W).

The gate stack GS including the plurality of gate lines 130 included in the memory cell array MCA may be disposed between the common source line CSL and the peripheral circuit structure PCS.

The peripheral circuit structure PCS may include a substrate 52, a plurality of circuits formed on the substrate 52, and a multi-layer wiring structure MWS for interconnecting the plurality of circuits or connecting the plurality of circuits to components in the memory cell region MEC of the cell array structure CAS.

The substrate 52 may include a semiconductor substrate. For example, the substrate 52 may include Si, Ge, or SiGe. An active region AC may be defined on the substrate 52 by a device isolation layer 54. A plurality of transistors TR constituting the plurality of circuits may be formed on the active region AC. The plurality of transistors TR may each include a gate dielectric layer PD and a gate PG sequentially stacked on the substrate 52 and a plurality of ion implantation regions PSD formed in the active region AC at both sides of the gate PG. The plurality of ion implantation regions PSD may each constitute a source region or a drain region of a transistor TR.

The multi-layer wiring structure MWS included in the peripheral circuit structure PCS may include a plurality of contact plugs 72 and a plurality of conductive lines 74. At least some of the plurality of conductive lines 74 may be configured to be electrically connected to the transistor TR. The plurality of contact plugs 72 may be configured to interconnect some transistors TR and some conductive lines 74. The plurality of transistors TR and the multi-layer wiring structure MWS included in the peripheral circuit structure PCS may be covered by an interlayer insulation layer 70. The interlayer insulation layer 70 may include a silicon oxide layer, a silicon nitride layer, a SiON layer, a SiOCN layer, or a combination thereof.

A plurality of circuits included in the peripheral circuit structure PCS may include various circuits included in the peripheral circuit 30 described with reference to FIG. 1. According to embodiments, the peripheral circuit structure PCS may further include unit elements like resistors and capacitors. The plurality of transistors TR, the plurality of contact plugs 72, and the plurality of conductive lines 74 included in the peripheral circuit structure PCS may constitute the plurality of circuits. The plurality of transistors TR may be configured to be electrically connected to the memory cell region MEC through a plurality of multi-layer wiring structures MWS, respectively. Each common source line CSL included in the cell array structure CAS may be spaced apart from the peripheral circuit structure PCS in the vertical direction (Z direction) with the memory cell region MEC therebetween.

The plurality of bit lines BL may each be connected to a wiring structure MS. The wiring structure MS may include a first upper wiring layer 172, a second upper wiring layer 174, and a third upper wiring layer 176. The first upper wiring layer 172, the second upper wiring layer 174, and the third upper wiring layer 176 may each include tungsten, titanium, tantalum, copper, aluminum, titanium nitride, tantalum nitride, tungsten nitride, or a combination thereof.

A plurality of first bonding metal pads 178A may be arranged on the top surface of the cell array structure CAS adjacent to the peripheral circuit structure PCS. The plurality of bit lines BL may be configured to be connected to the plurality of first bonding metal pads 178A through the wiring structure MS, respectively. In the cell array structure CAS, the wiring structure MS and the plurality of first bonding metal pads 178A may each be covered or overlapped by an interlayer insulation layer 150. The interlayer insulation layer 150 may include a silicon oxide layer, a silicon nitride layer, or a combination thereof.

The peripheral circuit structure PCS may be spaced apart from the plurality of channel structures 180 with the plurality of bit lines BL therebetween. The peripheral circuit structure PCS may include a plurality of second bonding metal pads 178B arranged on the multi-layer wiring structure MWS. The plurality of second bonding metal pads 178B may be configured to be connected to a plurality of circuits included in the peripheral circuit structure PCS. In the peripheral circuit structure PCS, the interlayer insulation layer 70 may cover or overlap the plurality of transistors TR, the plurality of contact plugs 72, the plurality of conductive lines 74, and the plurality of second bonding metal pads 178B.

The plurality of second bonding metal pads 178B may be bonded to the plurality of first bonding metal pads 178A included in the cell array structure CAS to be electrically connected to the plurality of first bonding metal pads 178A. The plurality of first bonding metal pads 178A and the plurality of second bonding metal pads 178B may constitute a plurality of bonding structures BS. The plurality of bit lines BL may be configured to be connected to at least one circuit selected from among the plurality of circuits included in the peripheral circuit structure PCS through a bonding structure BS including the first bonding metal pad 178A and the second bonding metal pad 178B.

According to embodiments, the plurality of contact plugs 72 and the plurality of conductive lines 74 in the peripheral circuit structure PCS may each include tungsten, aluminum, copper, or a combination thereof but are not limited thereto. The device isolation layer 54 may include a silicon oxide layer, a silicon nitride layer, or a combination thereof. The interlayer insulation layer 70 may include a silicon oxide layer, a silicon nitride layer, or a combination thereof. The plurality of first bonding metal pads 178A and the plurality of second bonding metal pads 178B constituting the bonding structure BS may each include copper, aluminum, or tungsten.

In the cell array structure CAS, the common source line CSL may be covered or overlapped by an insulation layer 106. The insulation layer 106 may include a silicon oxide film. Although not shown, the insulation layer 106 may be covered by a protective layer. The protective layer may include a polyimide-based material layer, such as photo sensitive polyimide (PSPI), but is not limited thereto.

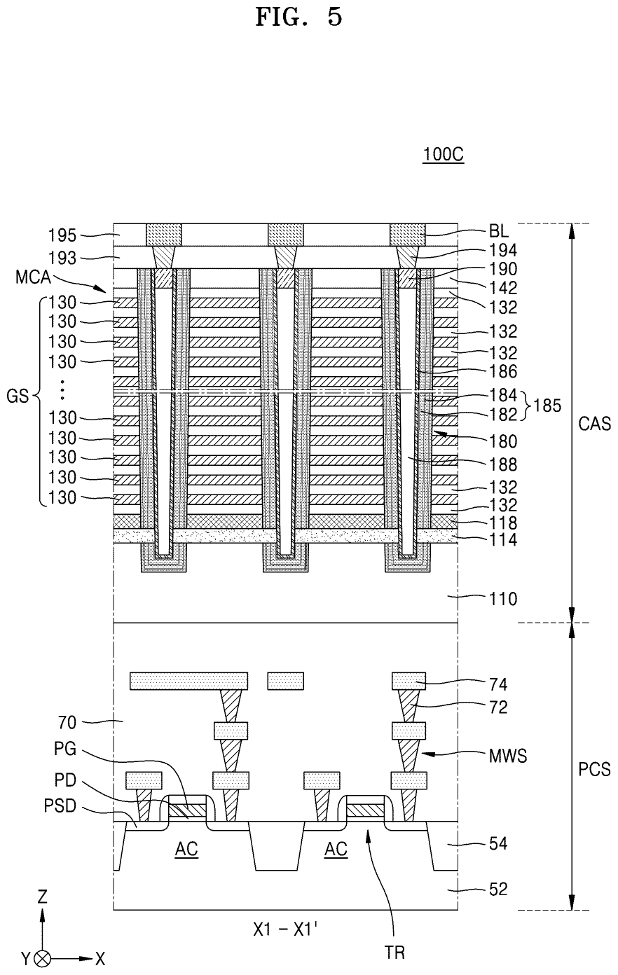

FIG. 5 is a cross-sectional view illustrating a semiconductor device 100C according to other embodiments. In FIG. 5, the same reference numerals as those in FIGS. 1 to 4 denote the same members, and detailed descriptions thereof will be omitted below.

Referring to FIG. 5, the semiconductor device 100C has substantially the same configuration as the semiconductor device 100B described above with reference to FIG. 4. However, the cell array structure CAS of the semiconductor device 100C includes a cell substrate 110 disposed on the peripheral circuit structure PCS and the gate stack GS disposed on the cell substrate 110.

In the cell array structure CAS, a first conductive plate 114 and a second conductive plate 118 may be sequentially arranged on the cell substrate 110, and the gate stack GS including the plurality of gate lines 130 may be disposed on the second conductive plate 118.

The cell substrate 110, the first conductive plate 114, and the second conductive plate 118 may function as the common source line CSL (refer to FIG. 1) for supplying a current to vertical memory cells included in the cell array structure CAS.

According to embodiments, the cell substrate 110 may include a semiconductor material such as doped polysilicon. The first conductive plate 114 and the second conductive plate 118 may each include a doped polysilicon layer, a metal layer, or a combination thereof. The metal layer may include tungsten (W) but is not limited thereto. The insulation pattern 132 may be provided between the second conductive plate 118 and the plurality of gate lines 130 and between the plurality of gate lines 130.

In the semiconductor device 100C, the peripheral circuit structure PCS may be spaced apart from the bit line BL with the plurality of gate lines 130 therebetween. The cell substrate 110 may be provided between the peripheral circuit structure PCS and the first conductive plate 114. The insulation plug 188, the channel film 186, and the multiple dielectric layer 185 of each of the plurality of channel structures 180 may extend through the first conductive plate 114 and the second conductive plate 118 in the vertical direction (Z direction), extend through a portion of the cell substrate 110 in the vertical direction (Z direction), and extend long in the vertical direction (Z direction). The first conductive plate 114 may extend through the multiple dielectric layer 185 in a horizontal direction and contact sidewalls of the channel film 186.

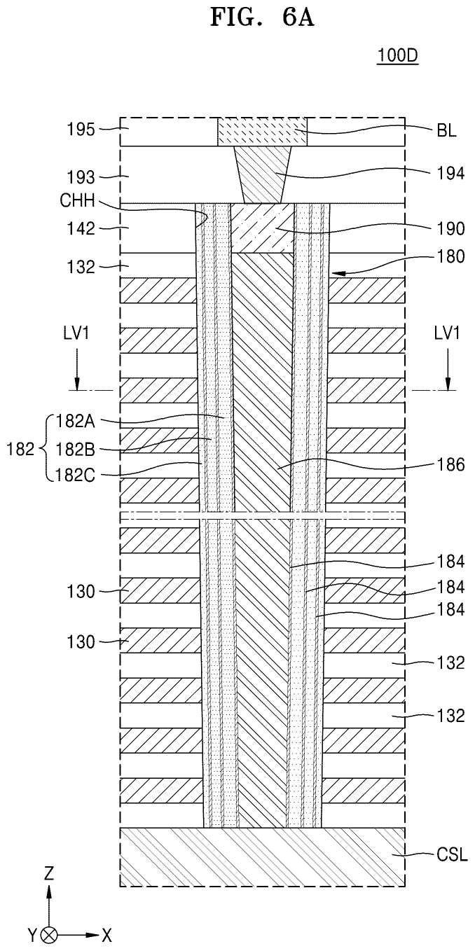

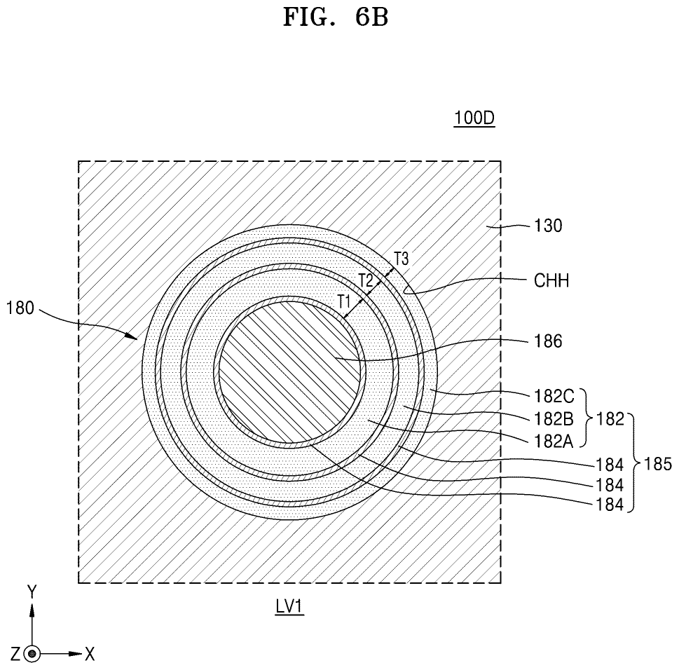

FIGS. 6A and 6B are diagrams illustrating a semiconductor device 100D according to other embodiments. FIG. 6A is an enlarged cross-sectional view of a region of the semiconductor device 100D corresponding to FIG. 2C. FIG. 6B is a plan view of the configuration of the semiconductor device 100D shown in FIG. 6A at the first vertical level LV1 and shows a region corresponding to FIG. 2E. In FIGS. 6A and 6N, the same reference numerals as those in FIGS. 2A to 2E denote the same members, and detailed descriptions thereof will be omitted below.

Referring to FIGS. 6A and 6B, the semiconductor device 100D has substantially the same configuration as the semiconductor device 100A described above with reference to FIGS. 2A to 2D. However, in the semiconductor device 100D, the insulation plug 188 of the semiconductor device 100A described above with reference to FIGS. 2A to 2E may be omitted.

According to some embodiments, the multiple dielectric layer 185 may cover or overlap the inner wall of the vertical hole CHH, extend long in the vertical direction (Z direction), and may have a hollow cylindrical shape. According to some embodiments, the channel film 186 may fill a space defined by the inner wall of the multiple dielectric layer 185 and may extend long in the vertical direction (Z direction).

Both the plurality of ferroelectric layers 182 and the plurality of interlayer dielectric layers 184 stacked in the vertical hole CHH may have high permittivity, and thus, the difference between the subthreshold swing (SS) characteristics of the upper portion of each of the plurality of channel structures 180 and the SS characteristics of the lower portion of each of the plurality of channel structures 180 may be reduced. Therefore, even when the insulation plug 188 is omitted in the plurality of channel structures 180, the electrical characteristics of the channel structure 180 may be maintained and process costs may be reduced.

According to some embodiments, the upper portion of the channel film 186 may surround the conductive pad 190. For example, the channel film 186 may cover or overlap sidewalls and the bottom surface of the conductive pad 190. The sidewalls of the conductive pad 190 may face the inner wall of the multiple dielectric layer 185 with the channel film 186 therebetween.

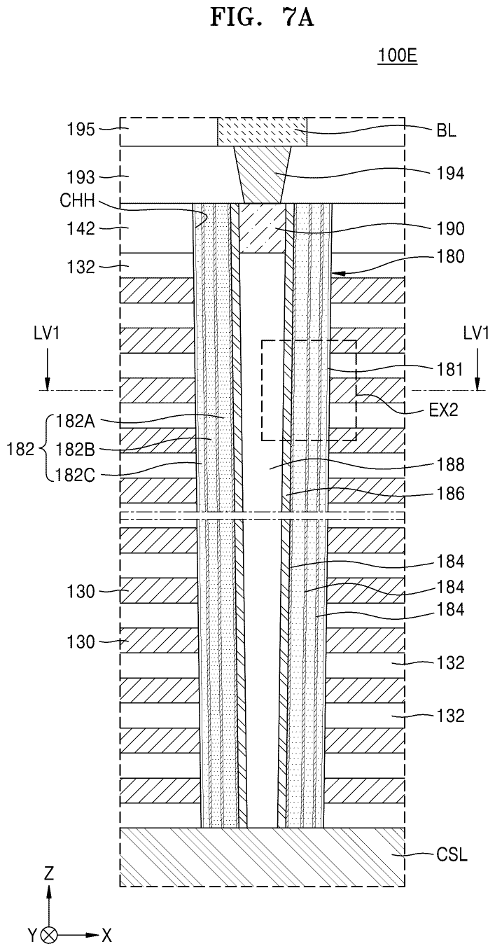

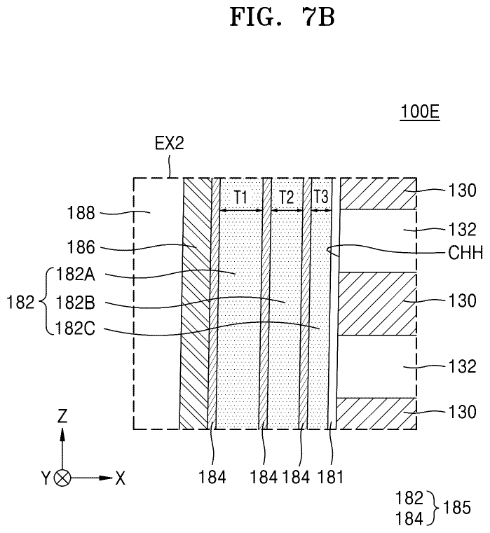

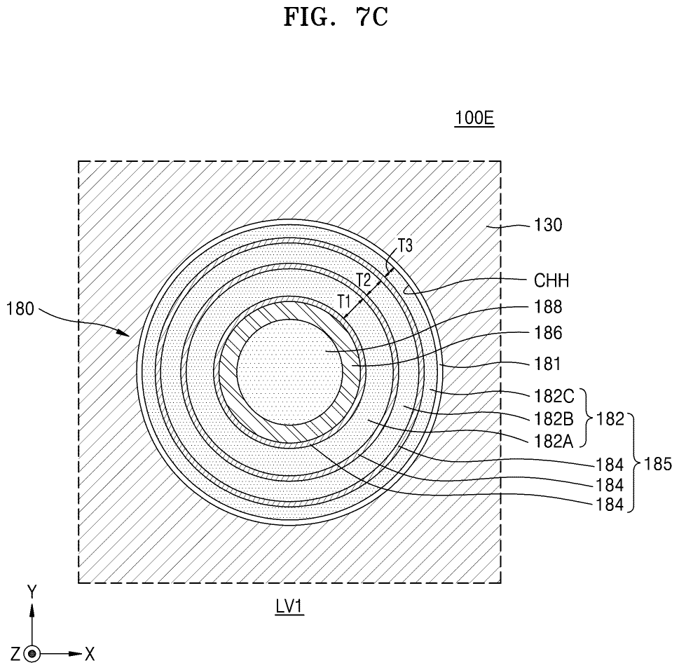

FIGS. 7A to 7C are diagrams illustrating a semiconductor device 100E according to other embodiments. FIG. 7A is an enlarged cross-sectional view of a region of the semiconductor device 100E corresponding to FIG. 2C. FIG. 7B is an enlarged cross-sectional view of a region of the semiconductor device 100E indicated by “EX2” in FIG. 7A and shows a region corresponding to FIG. 2D. FIG. 7C is a plan view of the configuration of the semiconductor device 100E shown in FIG. 7A at the first vertical level LV1 and shows a region corresponding to FIG. 2E. In FIGS. 7A to 7C, the same reference numerals as those in FIGS. 2A to 2E denote the same members, and detailed descriptions thereof will be omitted below.

Referring to FIGS. 7A to 7C, the semiconductor device 100E has substantially the same configuration as the semiconductor device 100A described above with reference to FIGS. 2A to 2D. However, the semiconductor device 100E may further include a trapping insulation layer 181 provided between the multiple dielectric layer 185 and the plurality of gate lines 130.

According to some embodiments, the trapping insulation layer 181 may cover or overlap the inner wall of the vertical hole CHH and extend long in the vertical direction (Z direction). For example, the trapping insulation layer 181 may have a hollow cylindrical shape. The insulation plug 188, the channel film 186, and the multiple dielectric layer 185 may fill a space defined by the trapping insulation layer 181. The inner wall of the trapping insulation layer 181 may contact the third ferroelectric layer 182C, and the outer wall of the trapping insulation layer 181 may contact the plurality of gate lines 130. During a memory operation of the semiconductor device 100E, electrons or holes are trapped at the interface between the trapping insulation layer 181 and the third ferroelectric layer 182C, and thus, a memory window may be expanded and electrical characteristics of the semiconductor device 100E may be improved.

According to some embodiments, the trapping insulation layer 181 may include at least one selected from among a silicon oxide layer, a silicon nitride layer, a silicon oxynitride layer, an oxide/nitride/oxide (ONO) layer, and a high-k layer having a higher dielectric constant than the silicon oxide layer.

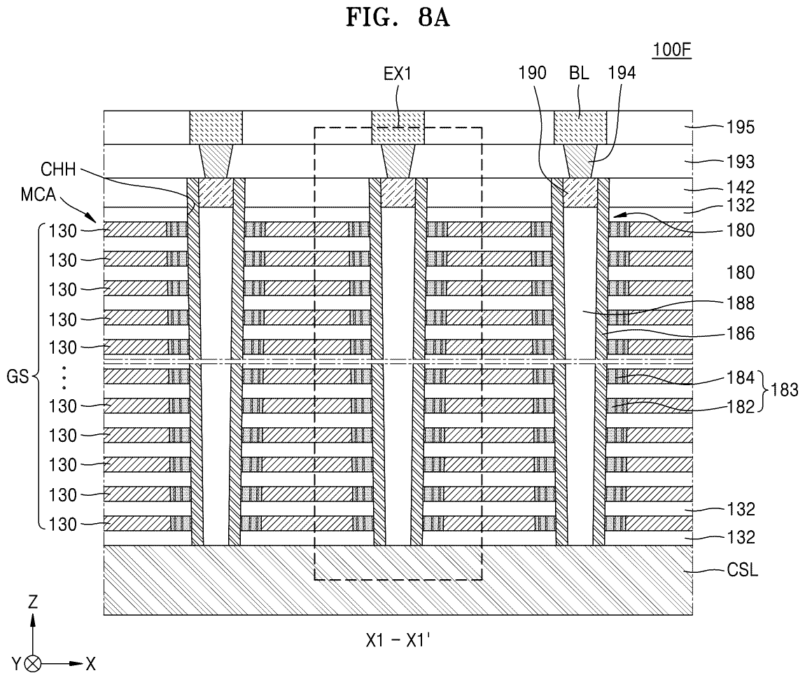

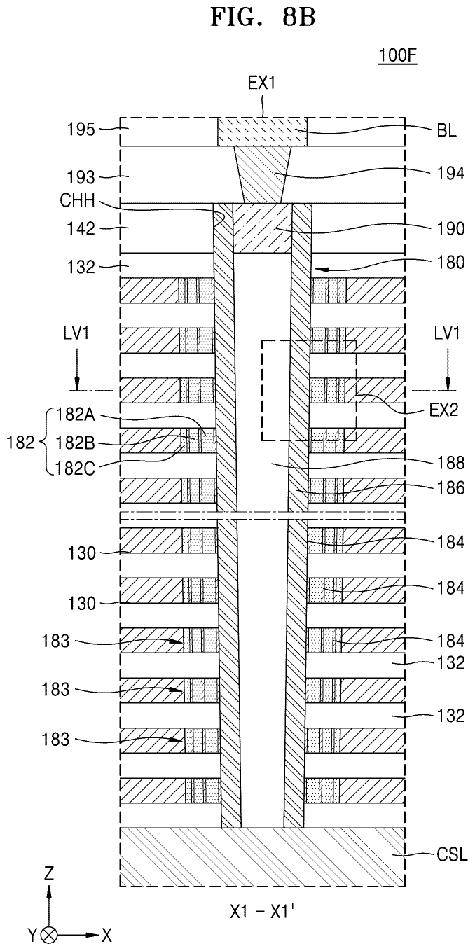

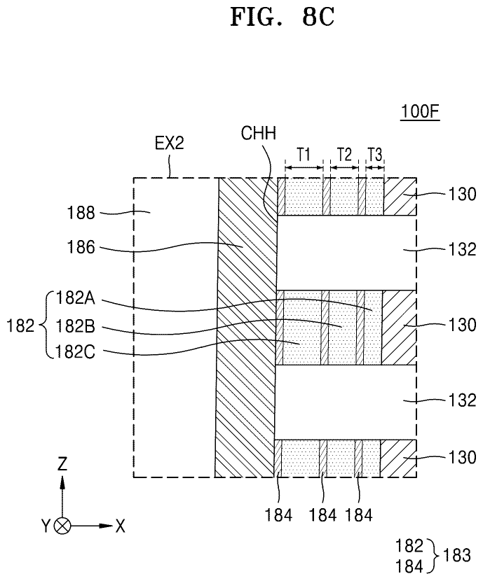

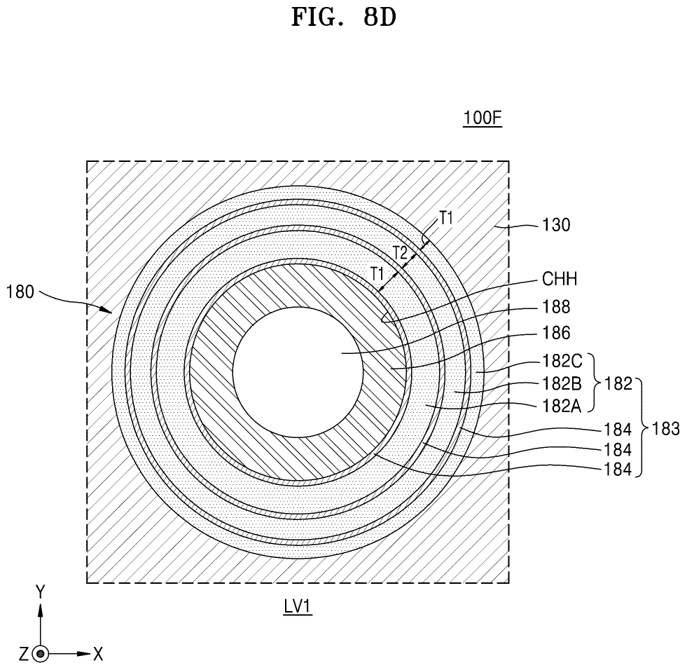

FIGS. 8A to 8D are diagrams illustrating a semiconductor device 100F according to other embodiments. FIG. 8A is an enlarged cross-sectional view of a region of the semiconductor device 100F corresponding to FIG. 2B. FIG. 8B is an enlarged cross-sectional view of a region of the semiconductor device 100F indicated by “EX1” in FIG. 8A and shows a region corresponding to FIG. 2C. FIG. 8C is an enlarged cross-sectional view of a region of the semiconductor device 100F indicated by “EX2” in FIG. 8A and shows a region corresponding to FIG. 2D. FIG. 8D is a plan view of the configuration of the semiconductor device 100F shown in FIG. 8B at the first vertical level LV1 and shows a region corresponding to FIG. 2E. In FIGS. 8A to 8D, the same reference numerals as those in FIGS. 2A to 2E denote the same members, and detailed descriptions thereof will be omitted below.

Referring to FIGS. 8A to 8D, the semiconductor device 100F has substantially the same configuration as the semiconductor device 100A described above with reference to FIGS. 2A to 2D. However, in the semiconductor device 100F, the plurality of interlayer dielectric layers 184 and the plurality of ferroelectric layers 182 are arranged between the plurality of insulation patterns 132 spaced apart from each other in the vertical direction (Z direction).

According to some embodiments, the vertical hole CHH may be filled with the channel film 186, the insulation plug 188, and the conductive pad 190. The channel film 186 may cover or overlap the inner wall of the vertical hole CHH and extend long in the vertical direction (Z direction). The outer wall of the channel film 186 may contact the plurality of insulation patterns 132. A space defined by the inner wall of the channel film 186 may be filled with the insulation plug 188 extending long in the vertical direction (Z direction) and the conductive pad 190 on the insulation plug 188.

According to some embodiments, a plurality of multiple dielectric film patterns 183 may be spaced apart from each other in the vertical direction (Z direction) and may surround the outer wall of the channel film 186. The plurality of multiple dielectric film patterns 183 may be arranged on the same vertical level as the plurality of gate lines 130, respectively, and the plurality of gate lines 130 may face the channel film 186 with the plurality of multiple dielectric film patterns 183 therebetween, respectively. The plurality of multiple dielectric film patterns 183 may each be arranged between the plurality of insulation patterns 132 in the vertical direction (Z direction). For example, the plurality of multiple dielectric film patterns 183 may vertically overlap the plurality of insulation patterns 132. The plurality of multiple dielectric film patterns 183 may each have a ring-like shape surrounding the channel film 186.

According to some embodiments, the plurality of multiple dielectric film patterns 183 may each include the plurality of interlayer dielectric layers 184 and the plurality of ferroelectric layers 182 alternately stacked on the channel film 186. For example, the plurality of interlayer dielectric layers 184 and the plurality of ferroelectric layers 182 may vertically overlap the plurality of insulation patterns 132. In this specification, the plurality of multiple dielectric film patterns 183 may each be referred to as a multiple dielectric film.

According to some embodiments, the outer wall of the channel film 186 may extend long in the vertical direction (Z direction) while contacting the plurality of insulation patterns 132 and the plurality of interlayer dielectric layers 184. The first ferroelectric layer 182A of each of the plurality of multiple dielectric film patterns 183 may face the channel film 186 with the innermost interlayer dielectric layer 184 from among the plurality of interlayer dielectric layers 184 therebetween. Third ferroelectric layers 182C of the plurality of multiple dielectric film patterns 183 may contact the plurality of gate lines 130, respectively.

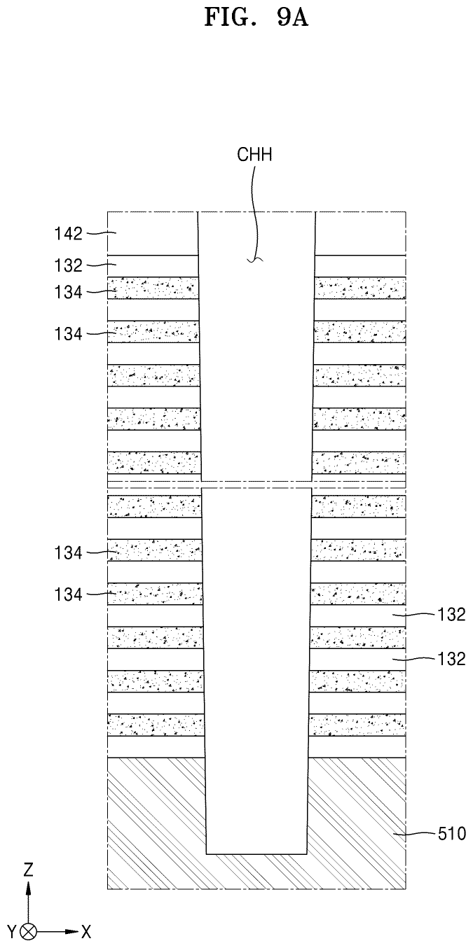

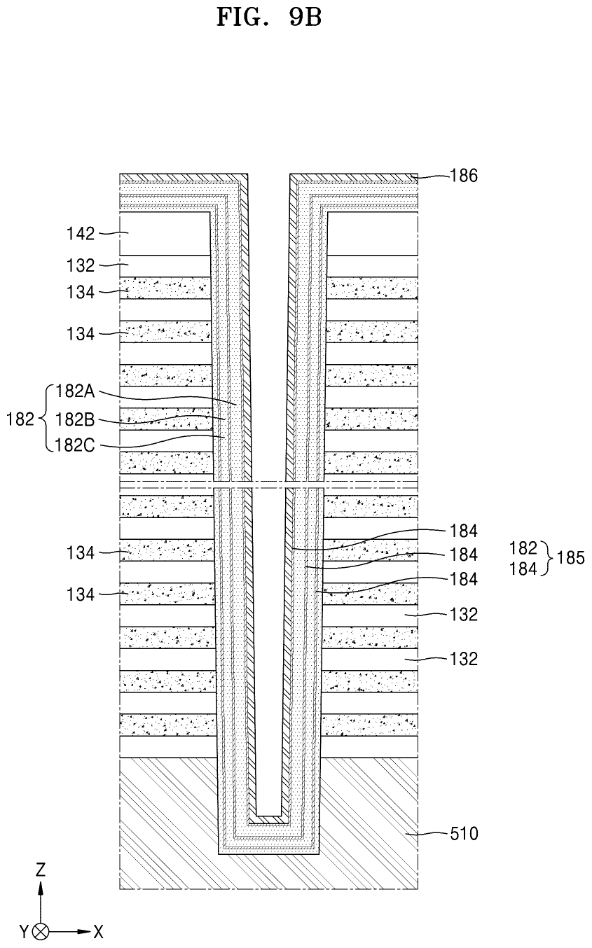

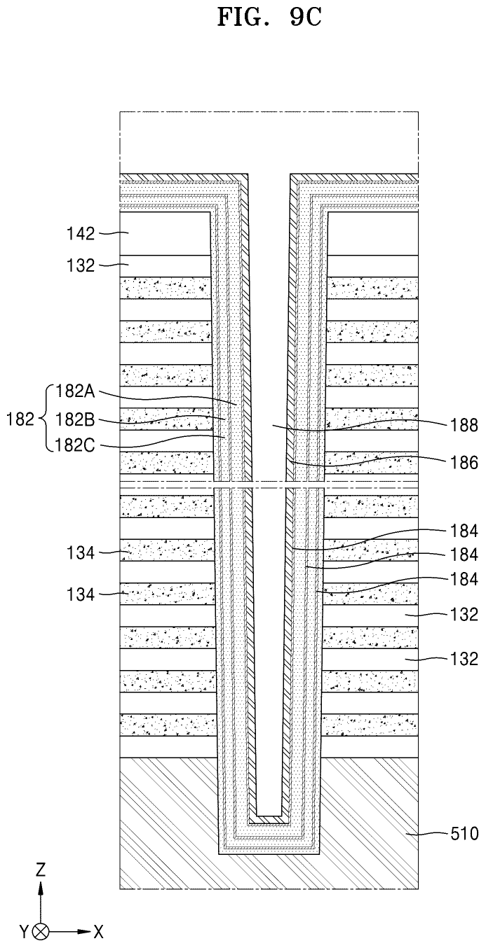

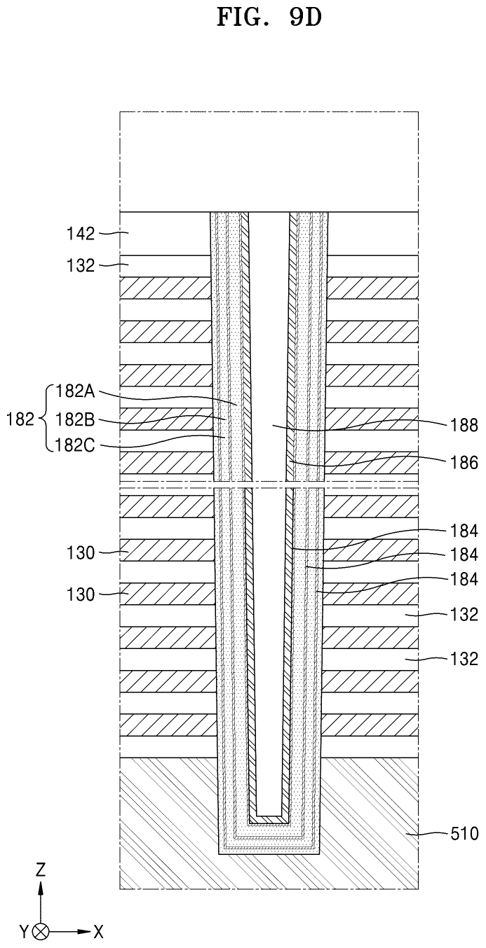

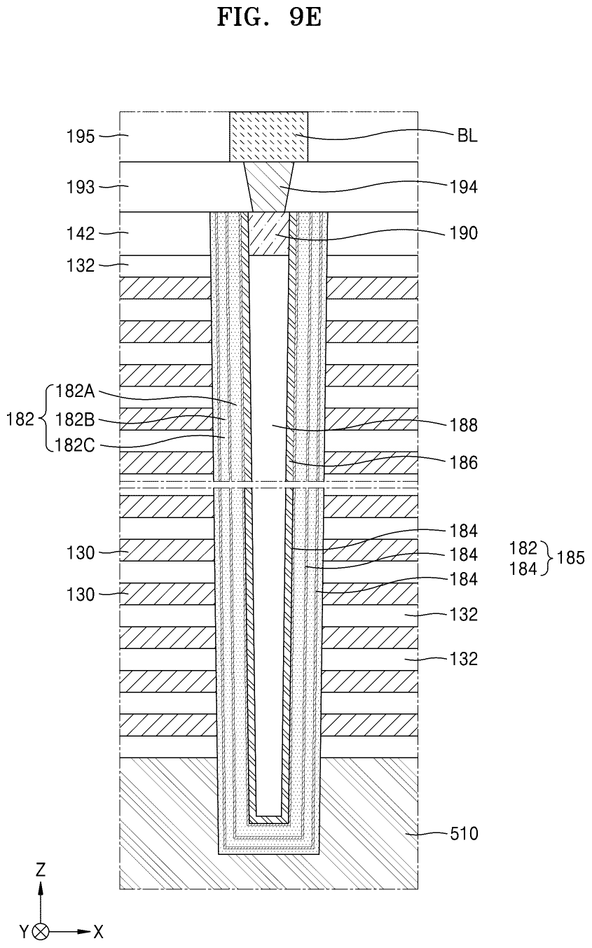

FIGS. 9A to 9E are cross-sectional views illustrating a method of manufacturing the semiconductor device 100A according to embodiments and are enlarged views of a region corresponding to the region indicated by “EX1” in FIG. 2B according to a process sequence. In FIGS. 9A to 9E, the same reference numerals as those in FIGS. 2A to 2E denote the same members, and detailed descriptions thereof will be omitted below.

Referring to FIG. 9A, after a plurality of insulation layers and a plurality of sacrificial insulation layers are alternately stacked one-by-one on a sacrificial substrate 510, the intermediate insulation layer 142 may be formed on the uppermost insulation layer from among the plurality of insulation layers. Thereafter, the vertical hole CHH extending through the plurality of insulation layers, the plurality of sacrificial insulation layers, and the intermediate insulation layer 142 and extending in the vertical direction (Z direction) may be formed, thereby forming the plurality of insulation patterns 132 and a plurality of sacrificial patterns 134 defining the vertical hole CHH. The vertical hole CHH may be formed to extend through a portion of the sacrificial substrate 510.

According to some embodiments, the sacrificial substrate 510 may include silicon. The plurality of insulation patterns 132 may include a silicon oxide film, and the plurality of sacrificial patterns 134 may include a silicon nitride film. The plurality of sacrificial patterns 134 may each secure a space for forming the gate stack GS (refer to FIGS. 2B to 2D) in subsequent processes.

Referring to FIG. 9B, in a result structure of FIG. 9A, the multiple dielectric layer 185 may be formed by alternately forming the plurality of ferroelectric layers 182 and the plurality of interlayer dielectric layers 184 on exposed surfaces inside and outside the vertical hole CHH. For example, after the third ferroelectric layer 182C is formed on the exposed surfaces inside and outside the vertical hole CHH, one interlayer dielectric layer 184 may be formed thereon, the second ferroelectric layer 182B and another interlayer dielectric layer 184 may be formed thereon, and then the first ferroelectric layer 182A and another interlayer dielectric layer 184 may be formed thereon. The second ferroelectric layer 182B may be formed to be thicker than the third ferroelectric layer 182C, and the first ferroelectric layer 182A may be formed to be thicker than the second ferroelectric layer 182B. Thereafter, the channel film 186 may be formed on the multiple dielectric layer 185.

Referring to FIG. 9C, in a result structure of FIG. 9B, the insulation plug 188 filling the remaining portion of the vertical hole CHH may be formed.

Referring to FIGS. 9C and 9D, the top surface of the intermediate insulation layer 142 may be exposed by planarizing a resultant structure of FIG. 9C. For the planarization, a chemical mechanical polishing (CMP) process may be used.

Thereafter, the plurality of word line cut regions WLC described above with reference to FIG. 2A may be formed in advance, and the plurality of sacrificial patterns 134 may be removed through the plurality of word line cut regions WLC. Thereafter, the plurality of gate lines 130 may be formed in spaces formed by removing the plurality of sacrificial patterns 134. After that, and as shown in FIG. 2A, the inside of each of the plurality of word line cut regions WLC may be filled with the word line cut structure 192.

Referring to FIG. 9E, in a result structure of FIG. 9D, a portion of the insulation plug 188 may be removed to provide a space above the vertical hole CHH, and the conductive pad 190 filling the space may be formed. Thereafter, the first upper insulation layer 193 covering or overlapping the conductive pad 190, the channel film 186, the multiple dielectric layer 185, and the intermediate insulation layer 142, the bit line contact pad 194 extending through the first upper insulation layer 193 and connected to the conductive pad 190, the second upper insulation layer 195, and the bit line BL extending through the second upper insulation layer 195 and connected to the bit line contact pad 194 may be formed.

According to other embodiments, to manufacture the semiconductor device 100B shown in FIG. 4, the wiring structure MS including a plurality of first upper wiring layers 172, a plurality of second upper wiring layers 174, and a plurality of third upper wiring layers 176, the plurality of first bonding metal pads 178A, and the interlayer insulation layer 150 filling spaces between the wiring structure MS and the plurality of first bonding metal pads 178A may be formed on the bit line BL. Also, the peripheral circuit structure PCS shown in FIG. 4 may be formed and the plurality of bonding structures BS may be formed by bonding the plurality of first bonding metal pads 178A included in the cell array structure CAS and the plurality of second bonding metal pads 178B included in the peripheral circuit structure PCS to each other, thereby forming the cell array structure CAS on the peripheral circuit structure PCS.

Referring to FIGS. 9E and 2C, the sacrificial substrate 510 is removed from a resultant structure of FIG. 9E and a result thereof is planarized, and thus, the insulation pattern 132, the multiple dielectric layer 185, the channel film 186, and the insulation plug 188 may be exposed. Thereafter, the common source line CSL covering or overlapping exposed surfaces of the insulation pattern 132, the multiple dielectric layer 185, the channel film 186, and the insulation plug 188 may be formed.

According to other embodiments, to manufacture the semiconductor device 100B shown in FIG. 4, the insulation layer 106 covering or overlapping the common source line CSL may be formed as shown in FIG. 4.

Although example methods of manufacturing the semiconductor device 100A shown in FIGS. 2A to 2E have been described with reference to FIGS. 9A to 9E, it should be understood that semiconductor devices having various structures variously modified and changes within the scope of the present disclosure may be manufactured based on the descriptions given with reference to FIGS. 9A to 9E.

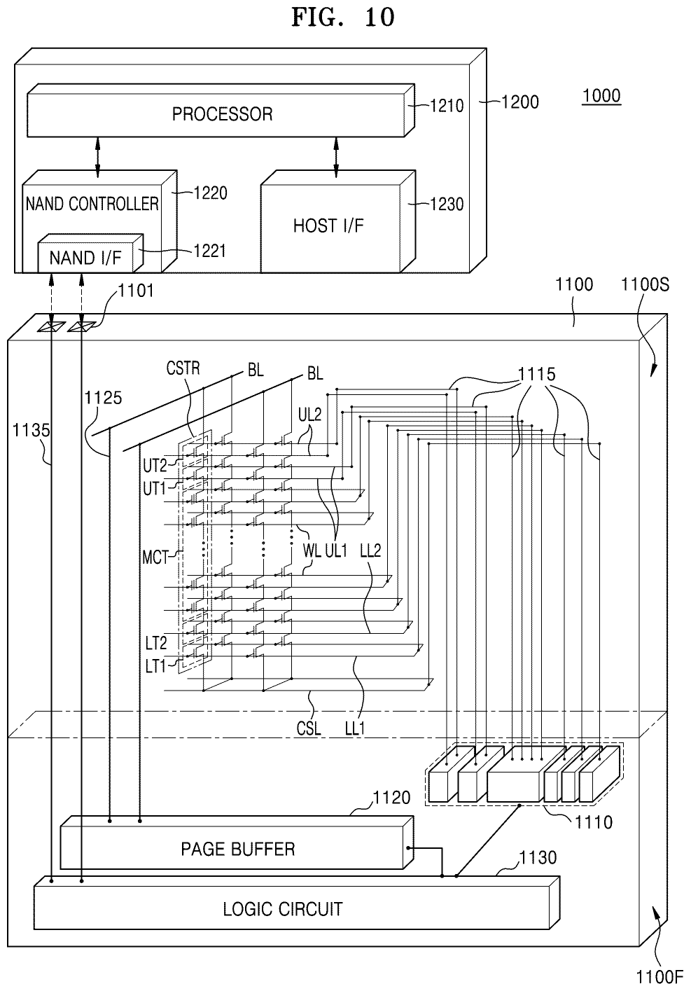

FIG. 10 is a diagram schematically showing an electronic system including a semiconductor device according to an embodiment.

Referring to FIG. 10, an electronic system 1000 according to an embodiment may include a semiconductor device 1100 and a controller 1200 electrically connected to the semiconductor device 1100. The electronic system 1000 may be a storage device including one or a plurality of semiconductor devices 1100 or an electronic device including the storage device. For example, the electronic system 1000 may be a solid state drive (SSD) device, a universal serial bus (USB), a computing system, a medical device, or a communication device including at least one semiconductor device 1100.

The semiconductor device 1100 may be a non-volatile memory device. For example, the semiconductor device 1100 may be a NAND flash memory device including at least one of the structures described above with respect to semiconductor devices 100A to 100F with reference to FIGS. 2A to 8D. The semiconductor device 1100 may include a first structure 1100F and a second structure 1100S on the first structure 1100F. According to embodiments, the first structure 1100F may also be disposed next to the second structure 1100S. The first structure 1100F may be a peripheral circuit structure including a decoder circuit 1110, a page buffer 1120, and a logic circuit 1130. The second structure 1100S may be a memory cell structure including the bit lines BL, the common source line CSL, the plurality of word lines WL, first and second gate upper lines UL1 and UL2, first and second gate lower lines LL1 and LL2, and a plurality of memory cell strings CSTR between the bit lines BL and the common source line CSL.

In the second structure 1100S, the plurality of memory cell strings CSTR may include lower transistors LT1 and LT2 adjacent to the common source line CSL, upper transistors UT1 and UT2 adjacent to the bit line BL, and a plurality of memory cell transistors MCT arranged between the lower transistors LT1 and LT2 and the upper transistors UT1 and UT2. The number of lower transistors LT1 and LT2 and the number of upper transistors UT1 and UT2 may vary in other embodiments.

According to embodiments, the upper transistors UT1 and UT2 may include string select transistors, and the lower transistors LT1 and LT2 may include ground select transistors. The first and second gate lower lines LL1 and LL2 may be gate electrodes of the lower transistors LT1 and LT2, respectively. The word line WL may be a gate electrode of a memory cell transistor MCT, and the first and second gate upper lines L1 and UL2 may be gate electrodes of the upper transistors UT1 and UT2, respectively.

The common source line CSL, the first and second gate lower lines LL1 and LL2, the plurality of word lines WL, and the first and second gate upper lines UL1 and UL2 may be electrically connected to the decoder circuit 1110 through a plurality of first connection wires 1115 extending from the inside of the first structure 1100F to the second structure 1100S. The plurality of bit lines BL may be electrically connected to the page buffer 1120 through a plurality of second connection wires 1125 extending from the inside of the first structure 1100F to the second structure 1100S.

In the first structure 1100F, the decoder circuit 1110 and the page buffer 1120 may execute a control operation on at least one of the plurality of memory cell transistors MCT. The decoder circuit 1110 and the page buffer 1120 may be controlled by the logic circuit 1130.

The semiconductor device 1100 may communicate with the controller 1200 through an input/output pad 1101 electrically connected to the logic circuit 1130. The input/output pad 1101 may be electrically connected to the logic circuit 1130 through an input/output connection wire 1135 extending from the inside of the first structure 1100F to the second structure 1100S.

The controller 1200 may include a processor 1210, a NAND controller 1220, and a host interface 1230. According to some embodiments, the electronic system 1000 may include a plurality of semiconductor devices 1100, and, in this case, the controller 1200 may control the plurality of semiconductor devices 1100.

The processor 1210 may control the overall operation of the electronic system 1000 including the controller 1200. The processor 1210 may operate according to a certain firmware and may access the semiconductor device 1100 by controlling the NAND controller 1220. The NAND controller 1220 may include a NAND interface 1221 that handles communication with the semiconductor device 1100. Control commands for controlling the semiconductor device 1100, data to be written to the memory cell transistors MCT of the semiconductor device 1100, and data to be read from the memory cell transistors MCT of the semiconductor device 1100 may be transmitted through the NAND interface 1221. The host interface 1230 may provide the function for communication between the electronic system 1000 and an external host. When a control command is received from an external host through the host interface 1230, the processor 1210 may control the semiconductor device 1100 in response to the control command.

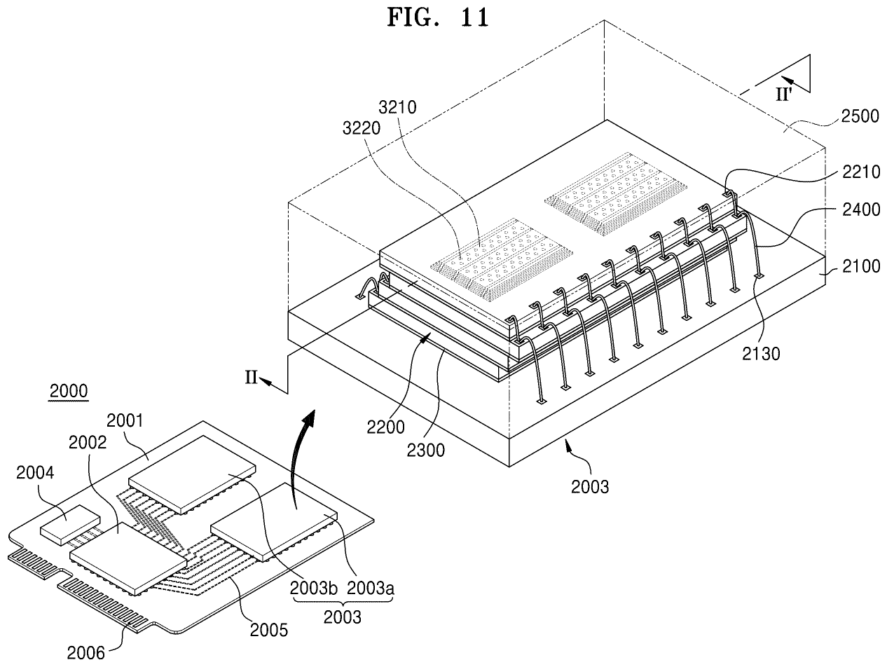

FIG. 11 is a schematic perspective view of an electronic system including a semiconductor device according to an embodiment.

Referring to FIG. 11, an electronic system 2000 according to an example embodiment of the present disclosure may include a main substrate 2001 and a controller 2002, one or more semiconductor packages 2003, and a DRAM 2004 that are mounted on the main substrate 2001. The semiconductor package 2003 and the DRAM 2004 may be connected to the controller 2002 by a plurality of wiring patterns 2005 formed on the main substrate 2001.

The main substrate 2001 may include a connector 2006 including a plurality of pins coupled to an external host. The number and arrangement of the pins of the connector 2006 may vary according to a communication interface between the electronic system 2000 and the external host. According to embodiments, the electronic system 2000 may communicate with an external host according to any one of interfaces including a universal serial bus (USB), peripheral component interconnect express (PCI-Express), serial advanced technology attachment (SATA), M-Phy for universal flash storage (UFS), etc. According to embodiments, the electronic system 2000 may operate by power supplied from an external host through the connector 2006. The electronic system 2000 may further include a power management integrated circuit (PMIC) that distributes power supplied from the external host to the controller 2002 and the semiconductor package 2003.

The controller 2002 may write data to or read data from the semiconductor package 2003 and may improve the operating speed of the electronic system 2000.

The DRAM 2004 may be a buffer memory for mitigating a speed difference between the semiconductor package 2003, which is a data storage space, and an external host. The DRAM 2004 included in the electronic system 2000 may also operate as a type of cache memory and may provide a space for temporarily storing data in a control operation for the semiconductor package 2003. When the DRAM 2004 is included in the electronic system 2000, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. The first and second semiconductor packages 2003a and 2003b may each be a semiconductor package including a plurality of semiconductor chips 2200. The first and second semiconductor packages 2003a and 2003b may each include a package substrate 2100, the semiconductor chips 2200 on the package substrate 2100, an adhesive layer 2300 disposed on the bottom surface of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including a plurality of package upper pads 2130. The semiconductor chips 2200 may each include input/output pads 2210. The input/output pad 2210 may correspond to the input/output pad 1101 of FIG. 10. The plurality of semiconductor chips 2200 may each include a plurality of gate stacks 3210 and a plurality of channel structures 3220. The plurality of semiconductor chips 2200 may each include at least one of the structures described above with respect to the semiconductor devices 100A to 100F with reference to FIGS. 2A to 8D.

According to embodiments, the connection structure 2400 may be a bonding wire electrically connecting the input/output pad 2210 and the package upper pad 2130. Therefore, in the first and second semiconductor packages 2003a and 2003b, the semiconductor chips 2200 may be electrically connected to one another through bonding wires and may be electrically connected to the package upper pads 2130 of the package substrate 2100. According to embodiments, in the first and second semiconductor packages 2003a and 2003b, the semiconductor chips 2200 may be connected to one another through a connection structure including through silicon vias (TSVs) instead of the connection structure 2400 including bonding wires.

According to embodiments, the controller 2002 and the semiconductor chips 2200 may be included in one package. According to embodiment, the controller 2002 and the semiconductor chips 2200 may be mounted on a separate interposer substrate different from the main substrate 2001 and the controller 2002 and the semiconductor chips 2200 may be connected to each other through wires formed on the interposer substrate.

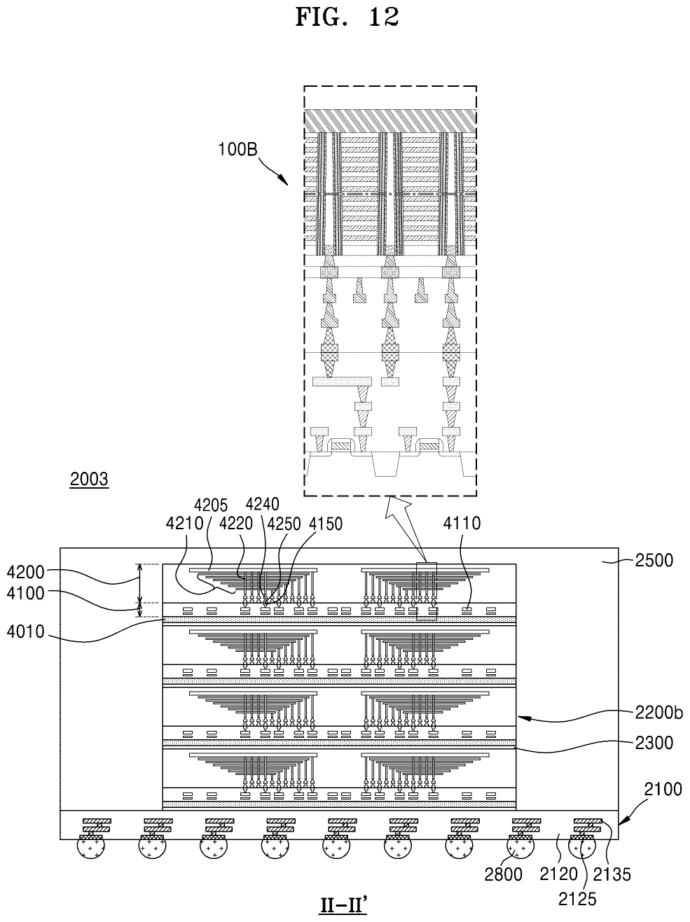

FIG. 12 is a schematic cross-sectional view of semiconductor packages according to embodiments. FIG. 12 shows a configuration along a line II-II′ of FIG. 11 in more detail.

Referring to FIG. 12, in the semiconductor package 2003, a plurality of semiconductor chips 2200b may each include a semiconductor substrate 4010, a first structure 4100 on the semiconductor substrate 4010, and a second structure 4200 bonded onto the first structure 4100 by a wafer bonding method.

The first structure 4100 may include a peripheral circuit region including peripheral wires 4110 and first junction structures 4150. The second structure 4200 includes a common source line 4205, a gate stack structure 4210 between the common source line 4205 and the first structure 4100, memory channel structures 4220 penetrating through the gate stack structure 4210, and second junction structures 4250 electrically and respectively connected to the word lines WL (FIG. 10) of the memory channel structures 4220 and the gate stack structure 4210. For example, the second junction structures 4250 may be electrically connected to the memory channel structures 4220 and the word lines WL (FIG. 10) through bit lines 4240 electrically connected to the memory channel structures 4220 and gate connection wires electrically connected to the word lines WL (FIG. 10). First junction structures 4150 of the first structure 4100 and the second junction structures 4250 of the second structure 4200 may be bonded to each other while contacting each other. Bonded portions of the first junction structures 4150 and the second junction structures 4250 may include, for example, copper (Cu).

The plurality of semiconductor chips 2200b may further include the input/output pads 2210 (FIG. 11) electrically connected to the peripheral wires 4110 of the first structure 4100.

The plurality of semiconductor chips 2200 of FIG. 11 and the plurality of semiconductor chips 2200b of FIG. 12 may be electrically connected to each other through the plurality of connection structures 2400 in the form of bonding wires. However, according to some embodiments, semiconductor chips in one semiconductor package, e.g., the plurality of semiconductor chips 2200 of FIG. 11 and the plurality of semiconductor chips 2200b of FIG. 12, may also be electrically connected to each other through a connection structure including TSVs.

While the present disclosure has been particularly shown and described with reference to embodiments thereof, it will be understood that various changes in form and details may be made therein without departing from the spirit and scope of the following claims.

What is claimed is:

1. A semiconductor device comprising:
a stacked structure comprising a plurality of gate lines and a plurality of insulation patterns that are alternately stacked in a vertical direction, wherein the stacked structure defines a vertical hole that extends into the stacked structure and in the vertical direction;
a channel film that extends into the vertical hole; and
a multiple dielectric layer structure between the channel film and the stacked structure, wherein the multiple dielectric layer structure comprises a plurality of interlayer dielectric layers and a plurality of ferroelectric layers that are alternately stacked and extend from the channel film toward the stacked structure, and
wherein an inner ferroelectric layer of the plurality of ferroelectric layers is thicker than an outer ferroelectric layer of the plurality of ferroelectric layers.

2. The semiconductor device of claim 1, wherein the plurality of ferroelectric layers comprise a monocrystalline ferroelectric material.

3. The semiconductor device of claim 1, further comprising a trapping dielectric layer between the multiple dielectric layer structure and the plurality of gate lines.

4. The semiconductor device of claim 1, wherein the plurality of ferroelectric layers comprise a third ferroelectric layer that is between the inner ferroelectric layer and the outer ferroelectric layer, and
a difference between a thickness of the inner ferroelectric layer and a thickness of the third ferroelectric layer is equal to a difference between the thickness of the third ferroelectric layer and the thickness of the outer ferroelectric layer.

5. The semiconductor device of claim 1, further comprising an insulation plug that is at least partially surrounded by the channel film in the vertical hole.

6. The semiconductor device of claim 1, wherein the multiple dielectric layer structure is on an outer wall of the channel film in the vertical hole and extends in the vertical direction.

7. The semiconductor device of claim 1, wherein the multiple dielectric layer structure has a hollow cylindrical shape, and
the channel film has a solid cylindrical shape and is in the vertical hole.

8. The semiconductor device of claim 1, wherein the multiple dielectric layer structure is between two adjacent insulation patterns from among the plurality of insulation patterns.

9. The semiconductor device of claim 1, wherein the plurality of ferroelectric layers comprise a same material.

10. The semiconductor device of claim 1, wherein the plurality of interlayer dielectric layers comprise a high-k material, wherein the high-k material comprises a dielectric constant that is greater than silicon oxide.

11. The semiconductor device of claim 1, wherein each of the plurality of ferroelectric layers has a thickness of 20 nm or less.

12. The semiconductor device of claim 1, wherein the multiple dielectric layer structure has a concentric circular cross-section shape.

13. A semiconductor device comprising:
a conductive layer;
a stacked structure on the conductive layer, wherein the stacked structure comprises a plurality of gate lines that are spaced apart from each other in a vertical direction and overlap each other in the vertical direction, wherein the stacked structure comprises a plurality of insulation patterns that are respectively between the plurality of gate lines, and wherein the stacked structure defines a vertical hole that extends into the stacked structure and in the vertical direction;
a conductive pad on the stacked structure and spaced apart from the conductive layer in the vertical direction;
a channel film in the vertical hole, wherein a first end of the channel film contacts the conductive layer and a second end of the channel film contacts the conductive pad; and
a multiple dielectric layer structure that extends in the vertical direction and is on an outer wall of the channel film in the vertical hole,
wherein the multiple dielectric layer structure comprises a plurality of interlayer dielectric layers and a plurality of ferroelectric layers that are alternately stacked on the outer wall of the channel film, and
an inner ferroelectric layer of the plurality of ferroelectric layers is thicker than an outer ferroelectric layer of the plurality of ferroelectric layers.

14. The semiconductor device of claim 13, wherein an outer wall of the outer ferroelectric layer contacts the plurality of gate lines, and
an inner interlayer dielectric layer from among the plurality of interlayer dielectric layers contacts the channel film.

15. The semiconductor device of claim 13, wherein the channel film has a solid cylindrical shape.

16. The semiconductor device of claim 13, wherein the plurality of ferroelectric layers comprise a monocrystalline material.

17. The semiconductor device of claim 13, further comprising a trapping dielectric layer that extends in the vertical direction and is on an outer wall of the multiple dielectric layer structure in the vertical hole,
wherein an inner wall of the trapping dielectric layer contacts the outer ferroelectric layer, and
an outer wall of the trapping dielectric layer contacts the plurality of gate lines.

18. An electronic system comprising:
a main substrate;
a semiconductor device on the main substrate; and
a controller electrically connected to the semiconductor device on the main substrate,
wherein the semiconductor device comprises:
a stacked structure comprising a plurality of gate lines and a plurality of insulation patterns that are alternately stacked in a vertical direction, wherein the stacked structure defines a vertical hole that extends into the stacked structure and in the vertical direction;
a channel film extending in the vertical direction and in the vertical hole; and
a multiple dielectric layer structure between the channel film and the stacked structure, wherein the multiple dielectric layer structure comprises a plurality of interlayer dielectric layers and a plurality of ferroelectric layers that are alternately stacked and extend from the channel film toward the stacked structure, and
wherein an inner ferroelectric layer of the plurality of ferroelectric layers is thicker than an outer ferroelectric layer of the plurality of ferroelectric layers.

19. The electronic system of claim 18, wherein the plurality of ferroelectric layers comprise a monocrystalline material.

20. The electronic system of claim 18, further comprising a trapping insulation layer between the multiple dielectric layer structure and the plurality of gate lines.
